(19) United States
(12) Patent Application Publication
(10) Pub. No.: US 2019/0166733 A1
(43) Pub. Date: May 30, 2019

(54) TWO-DIMENSIONAL METAL CARBIDE, NITRIDE, AND CARBONITRIDE FILMS AND COMPOSITES FOR EMI SHIELDING

(71) Applicants: Drexel University, Philadelphia, PA (US); Korea Institute of Science and Technology, Seoul (KR)

(72) Inventors: Yury GOGOTSI, Warminster, PA (US); Babak ANASORI, Norristown, PA (US); Mohamed H. ALHABEB, Philadelphia, PA (US); Christine B. HATTER, Pennsauken, NJ (US); Chong Min KOO, Seoul (KR); Soon Man HONG, Seoul (KR); Faisal SHAHZAD, Seoul (KR)

(21) Appl. No.: 16/092,338

(22) PCT Filed: Apr. 21, 2017
(86) PCT No.: PCT/US2017/028800

§ 371 Date: Oct. 9, 2018

Related U.S. Application Data
(60) Provisional application No. 62/326,074, filed on Apr. 22, 2016.

(51) Int. Cl. H05K 9/00; H01B 1/20

(52) U.S. Cl. CPC H05K 9/0088; C01B 32/921; H01B 1/20

(57) ABSTRACT

The present disclosure is directed to materials which provide electromagnetic shielding and methods of providing such electromagnetic shielding. In particular, the present disclosure describes the use of two-dimensional transition metal carbide, nitride, and carbonitride materials for this purpose.

### CROSS REFERENCE TO RELATED APPLICATIONS

This application claims priority to U.S. Patent Application Ser. No. 62/326,074, filed Apr. 22, 2016, the contents of which are incorporated by reference in their entirety for all purposes.

### TECHNICAL FIELD

The present disclosure is directed to materials which provide electromagnetic interference shielding and methods of providing such electromagnetic shielding.

### BACKGROUND

In 2011, a new family of two-dimensional (2D) crystalline transition metal carbides, so called MXenes, were discovered at Drexel University. In 2015, the family further expanded with the discovery of double transition metal (double M) MXenes. To date, there are about 20 different MXene compositions such as Ti₂C, Ti₂N, Ti₃C₂, Ti₃N₂, Nb₂C, Nb₂N, V₂C, V₂N, Ta₄C₃, Mo₂TiC₂, Mo₂Ti₂C₃, Cr₂TiC₂, etc. have been synthesized. The majority of MXenes have very high metallic conductivities.

### SUMMARY

This disclosure reveals the unexpectedly high EMI shielding effectiveness of two-dimensional (2D) crystalline transition metal carbides, including MXene films and MXene-polymer composites with capabilities that show them to outperform any known EMI shielding values, with the exception of pure metals. The high values of EMI shielding reported herein for compositions comprising the nominal compositions Mₙ₊₁Xₙ, is seen as representative of the wider range of two-dimensional (2D) transition metal carbides, nitrides, and carbonitrides, including compositions comprising the nominal crystalline compositions M′₂M″ₙXₙ₊₁, where M, M′, M″, and X are defined herein. Also, while sometimes described herein in term of carbides, embodiments comprising the corresponding nitrides and carbonitrides are also considered within the scope of the invention.

Among the embodiments of the present invention are those methods for shielding an object from electromagnetic interference comprising superposing at least one surface of the object (i.e., contacting or non-contacting the surface) with a coating comprising a two-dimensional transitional metal carbide, nitride, or carbonitride composition having electrically conductive surfaces. Such two-dimensional materials include MX-ene compositions; i.e., those comprising the nominal unit cell composition Mₙ₊₁Xₙ. While a range of such compositions are exemplified herein, the invention is not limited to those compositions so exemplified, and include any and all of the compositions described herein, for example, those having crystalline phase stoichiometries of Mₙ₊₁Xₙ, wherein M is at least one Group IIIB, IVB, VB, or VIB metal, each X is C, N, or a combination thereof, and n=1, 2, or 3.

MXenes are one of a family of two dimensional (2D) transition metal carbides, nitrides, and carbonitrides, MXenes described as having a formula of Mₙ₊₁XₙTₓ, where M is an early transition metal (e.g. Sc, Y, Ti, Zr, Hf, V, Nb, Ta, Cr, Mo, W, and Lu), X is carbon and/or nitrogen. In MXenes, 2D metal carbide flakes are terminated with surface functional groups such as (—OH, ═O and —F), represented with Tₓ. This combination gives MXenes exceptional electrical conductivity and good mechanical properties coupled with hydrophilicity, which makes them a good candidate to be used in polymer composites. Both free-standing polymer composites exhibited good conductivity at low polymer loadings, and improved tensile strength in the Ti₃C₂Tₓ-PVA composites. Other compositions, sometimes also referred to as MXenes, include compositions having an empirical formula of M′₂M″ₙXₙ₊₁, such that each X is positioned within an octahedral array of M′ and M″, and where M″ₙ are present as individual two-dimensional array of atoms sandwiched between a pair of two-dimensional arrays of M′ atoms, wherein M′ and M″ are different Group IIIB, IVB, VB, or VIB metals (especially where M′ and M″ are Ti, V, Nb, Ta, Cr, Mo, W, Sc, Y, Zr, Hf, Lu, or a combination thereof), each X is C and/or N; and n=1 or 2,

In still other embodiments, the two-dimensional transition metal carbide comprises a composition having an empirical formula of M′₂M″ₙXₙ₊₁, such that each X is positioned within an octahedral array of M′ and M″, and where M″ₙ are present as individual two-dimensional array of atoms sandwiched between a pair of two-dimensional arrays of M′ atoms, wherein M′ and M″ are different Group IIIB, IVB, VB, or VIB metals (especially where M′ and M″ are Ti, V, Nb, Ta, Cr, Mo, W, Lu, Sc, Y, Zr, Hf, or a combination thereof), each X is C and/or N; and n=1 or 2.

In preferred embodiments, the two-dimensional transition metal carbide composition comprises titanium. In some of these embodiments, the two-dimensional transition metal carbide is described in terms of Mo₂TiC₂, Mo₂Ti₂C₃, Ti₃C₂, Mo₂TiC₂Tₓ, Mo₂Ti₂C₃Tₓ, or Ti₃C₂Tₓ.

In other preferred embodiments, the coating comprises a polymer composite comprising an organic polymer, including for example, a polysaccharide polymer, preferably an alginate or modified polymer, and the two-dimensional transition metal carbide. In some of these embodiments, the polymers/copolymers and MXene material are present in a weight ratio range of from about 2:98 to about 98:2. These coatings may also comprise an inorganic composite comprising a glass.

In some embodiments, the coating comprises an electrically conductive or semi-conductive surface, preferably having a surface conductivity of at least 250 S/cm, 2500 S/cm, 4500 S/cm, or higher (to about 8,000 S/cm). In some embodiments, the coating has a thickness in a range of from about 2 to about 12 microns, or higher.

These coatings can exhibits an EMI shielding, over a frequency range of from 8 to 13 GHz, in a range of from about 10 to about 65 dB, or higher.

Still other embodiments include bonded composite compositions, optionally present as coatings, comprising any one or more of the two-dimensional metal carbide, nitride, or carbonitride materials described herein and one or more polymers and copolymers comprising oxygen-containing functional groups (e.g., —OH and/or —COOH) and/or amine-containing functional groups and/or thiol-containing functional groups (such as described herein), wherein the oxygen-containing functional groups (—OH, —COO, and ═O) and/or amine-containing functional groups and/or thiol are bonded (or capable of bonding) with the surface functionalities of the two-dimensional metal carbide materials. These compositions include those where the polymers/copolymers and two-dimensional metal carbide materials are present in a weight ratio range of from about 1:99 to about 98:2, or a range combining two or more of these ranges. These composite coatings exhibit the electrical, thickness, and EMI shielding effectiveness properties as described in the context of the method embodiments.

While the claims are provided in terms of methods of shielding objects, it should be appreciated that the disclosure also encompasses those novel compositions providing the level of shielding, and additional claims configured to describe such compositions are also within the scope of the present disclosure.

### BRIEF DESCRIPTION OF THE DRAWINGS

The present application is further understood when read in conjunction with the appended drawings. For the purpose of illustrating the subject matter, there are shown in the drawings exemplary embodiments of the subject matter; however, the presently disclosed subject matter is not limited to the specific methods, devices, and systems disclosed. In addition, the drawings are not necessarily drawn to scale. In the drawings:

FIG. 1A shows a schematic representation of the structural differences between Ti₃C₂T films (T=terminal groups) and the Ti₃C₂-sodium alginate composite. FIG. 1B shows a SEM cross sectional image of Ti₃C₂ (average thickness 11.2 microns); FIG. 1C shows a SEM cross sectional image of Ti₃C₂-composite (average thickness 6.5 microns). FIGS. 1D-1F shows the morphological differences between Ti₃C₂-sodium alginate composites of different loadings. FIG. 1G shows XRD patterns of Ti₃C₂-sodium alginate composites of different loadings. FIG. 1H shows a TEM image of a representative Ti₃C₂-sodium alginate composites

FIGS. 2A-B show EMI shielding effectiveness for Ti₃C₂ as a function of frequency.

FIGS. 3A-B show EMI shielding effectiveness for Mo₂Ti₂C₃ and Mo₂TiC₂, respectively, as a function of frequency. FIG. 3C shows the corresponding electrical conductivity of several different MXenes. FIG. 3D shows the electrical conductivity of the Ti₃C₂-sodium alginate composites of different loadings. FIG. 3E shows another comparison of the EMI shielding effectiveness of several different MXenes. FIG. 3F shows the effect of thickness on EMI shielding effectiveness. FIGS. 3G-H shows the effect of loading on the EMI shielding effectiveness of a sodium alginate composite (ca. 8-9 microns). FIG. 3I shows the EMI contribution (reflection and absorption for Ti₃C₂ and one of the Ti₃C₂-sodium alginate composites.

FIG. 4 shows EMI shielding effectiveness for Ti₃C₂-sodium alginate composites as a function of frequency.

FIG. 5 shows EMI shielding effectiveness comparison of various MXene films at thicknesses of ca. 2 microns.

FIG. 6 show EMI shielding effectiveness comparison of Ti₃C₂ and aluminum foil.

FIG. 7 shows EMI shielding effectiveness comparison of various MXene films as a function of thickness in comparison with other compositions (see also Table 3).

FIG. 8 shows specific EMI shielding of MXene and other materials. SSE/t vs. thickness comparison of MXenes and their composites with previously reported EMI shielding materials. Data derived from data in Table 3.

FIG. 9 shows EMI SE comparison of MXene and its composite with known materials of comparable thickness. Measured EMI SE (maximum) values of thin films of sodium alginate (thickness: 9 μm), 90 wt. % Ti₃C₂Tₓ-SA (8 μm), Ti₃C₂Tₓ (11.2 μm), aluminum (8 μm) and copper (10 μm) in X-band range. Sodium alginate being electrical insulator is transparent to electromagnetic waves (close to 0 dB). For comparison, a previously reported value for rGO film (8.4 μm thick) is shown. Data derived from data in Table 3.

FIG. 10 shows a schematic of possible mechanisms contributing to EMI shielding.

### DETAILED DESCRIPTION OF ILLUSTRATIVE EMBODIMENTS

The present invention is directed to compositions and methods of providing EMI shielding.

As technology evolves, the effectiveness of electromagnetic radiation on electronics and their components become increasingly important. Electromagnetic interference (EMI) is emitted by any electronic device that transmits, distributes, or utilizes electrical energy. Hence, as electronics and their components operate at faster speeds and become smaller in size there will be a significant increase in EMI resulting in potential malfunctioning and degradation of electronics. This increase in electromagnetic pollution can also cause potential harm to the human body as well if no shielding is present.

For an EMI shielding material to be effective, it must both reduce undesirable emissions and protect the component from random external signals. The primary function of EMI shielding is to reflect radiation through the use of charge carriers that interact directly with the electromagnetic fields. As a result, shielding materials tend to be electrically conductive; however, high conductivity is not a specific requirement. The secondary mechanism of EMI shielding requires absorption of EMI radiation due to electric and/or magnetic dipoles of the field interacting with the radiation. Previously, metal shrouds were the material of choice to combat EMI pollution, but with smaller devices and components, metal shrouds add additional weight making them less desirable. As a result, lightweight, low-cost, high strength and easily fabricated shielding materials are more favorable. Polymer-matrix composites with embedded conductive fillers have become a popular alternative for EMI shielding due to high processability and low densities. However, current EMI shielding values for these materials are still not very high.

The present invention is directed to methods of shielding an object from electromagnetic interference. In certain embodiments, these methods comprise superposing at least one surface of the object (i.e., contacting or non-contacting the surface) with a coating comprising a two-dimensional transitional metal carbide, nitride, or carbonitride composition having electrically conductive surfaces. As described elsewhere herein, these two-dimensional compositions generally comprise crystalline two-dimensional transition metal carbides, nitride, or carbonitride. Also, while sometimes described herein in term of carbides, embodiments comprising the use of the corresponding nitrides and carbonitrides within the MXene umbrella are also considered within the scope of the invention

These compositions are also sometimes described in terms of the phrase “MX-enes” or “MX-ene compositions.” MXenes may be described as a two-dimensional transition metal carbide, nitride, or carbonitrides comprising at least one layer having first and second surfaces, each layer comprising:

a substantially two-dimensional array of crystal cells,

each crystal cell having an empirical formula of Mₙ₊₁Xₙ, such that each X is positioned within an octahedral array of M,

wherein M is at least one Group IIIB, IVB, VB, or VIB metal,

wherein each X is C, N, or a combination thereof, preferably C;

n=1, 2, or 3.

These so-called MXene compositions have been described in U.S. Pat. No. 9,193,595 and Application PCT/US2015/051588, filed Sep. 23, 2015, each of which is incorporated by reference herein in its entirety at least for its teaching of these compositions, their (electrical) properties, and their methods of making. That is, any such composition described in this patent is considered as applicable for use in the present methods and within the scope of the present invention. For the sake of completeness, M can be at least one of Sc, Y, Lu, Ti, Zr, Hf, V, Nb, Ta, Cr, Mo, or W. Certain of these compositions include those having one or more empirical formula wherein Mₙ₊₁Xₙ comprises Sc₂C, Ti₂C, V₂C, Cr₂C, Cr₂N, Zr₂C, Nb₂C, Hf₂C, Ti₃C₂, V₃C₂, Ta₃C₂, Ti₄C₃, V₄C₃, Ta₄C₃, Sc₂N, Ti₂N, V₂N, Cr₂N, Cr₂N, Zr₂N, Nb₂N, Hf₂C, Ti₃N₂, V₃C₂, Ta₃C₂, Ti₄N₃, V₄C₃, Ta₄N₃ or a combination or mixture thereof. In particular embodiments, the Mₙ₊₁Xₙ structure comprises Ti₃C₂, Ti₂C, Ta₄C₃ or (V_{1/2}Cr_{1/2})₃C₃. In some embodiments, M is Ti or Ta, and n is 1, 2, or 3, for example having an empirical formula Ti₃C₂ or Ti₂C and wherein at least one of said surfaces of each layer has surface terminations comprising hydroxide, oxide, sub-oxide, or a combination thereof.

In other embodiments, the methods use compositions, wherein the two-dimensional transition metal carbide, nitrides, or carbonytride comprises a composition comprising at least one layer having first and second surfaces, each layer comprising:

a substantially two-dimensional array of crystal cells,

each crystal cell having an empirical formula of M′₂M″ₙXₙ₊₁, such that each X is positioned within an octahedral array of M′ and M″, and where M″ₙ are present as individual two-dimensional array of atoms intercalated (sandwiched) between a pair of two-dimensional arrays of M′ atoms,

wherein M′ and M″ are different Group IIIB, IVB, VB, or VIB metals (especially where M′ and M″ are Ti, V, Nb, Ta, Cr, Mo, or a combination thereof),

wherein each X is C, N, or a combination thereof, preferably C; and

n=1 or 2.

These compositions are described in greater detail in Application PCT/US2016/028354, filed Apr. 20, 2016, which is incorporated by reference herein in its entirety at least for its teaching of these compositions and their methods of making. For the sake of completeness, in some embodiments, M′ is Mo, and M″ is Nb, Ta, Ti, or V, or a combination thereof. In other embodiments, n is 2, M′ is Mo, Ti, V, or a combination thereof, and M″ is Cr, Nb, Ta, Ti, or V, or a combination thereof. In still further embodiments, the empirical formula M′₂M″ₙXₙ₊₁ comprises Mo₂TiC₂, Mo₂VC₂, Mo₂TaC₂, Mo₂NbC₂, Mo₂Ti₂C₃, Cr₂TiC₂, Cr₂VC₂, Cr₂TaC₂, Cr₂NbC₂, Ti₂NbC₂, Ti₂TaC₂, V₂TaC₂, or V₂TiC₂, preferably Mo₂TiC₂, Mo₂VC₂, Mo₂TaC₂, or Mo₂NbC₂, or their nitride or carbonitride analogs. In still other embodiments, M′₂M″ₙXₙ₊₁ comprises Mo₂Ti₂C₃, Mo₂V₂C₃, Mo₂Nb₂C₃, Mo₂Ta₂C₃, Cr₂Ti₂C₃, Cr₂V₂C₃, Cr₂Nb₂C₃, Cr₂Ta₂C₃, Nb₂Ta₂C₃, Ti₂Nb₂C₃, Ti₂Ta₂C₃, V₂Ta₂C₃, V₂Nb₂C₃, or V₂Ti₂C₃, preferably Mo₂Ti₂C₃, Mo₂V₂C₃, Mo₂Nb₂C₃, Mo₂Ta₂C₃, Ti₂Nb₂C₃, Ti₂Ta₂C₃, or V₂Ta₂C₃, or their nitride or carbonitride analogs.

Each of these compositions having empirical crystalline formulae Mₙ₊₁Xₙ or M′₂M″ₙXₙ₊₁ are described in terms of comprising at least one layer having first and second surfaces, each layer comprising a substantially two-dimensional array of crystal cells. In some embodiments, these compositions comprise layers of individual two-dimensional cells. In other embodiments, the compositions comprise a plurality of stacked layers. Additionally, in some embodiments, at least one of said surfaces of each layer has surface terminations (optionally designated “Tₛ” or “Tₓ”) comprising alkoxide, carboxylate, halide, hydroxide, hydride, oxide, sub-oxide, nitride, sub-nitride, sulfide, thiol, or a combination thereof. In some embodiments, at least one of said surfaces of each layer has surface terminations comprising alkoxide, fluoride, hydroxide, oxide, sub-oxide, or a combination thereof. In still other embodiments, both surfaces of each layer have said surface terminations comprising alkoxide, fluoride, hydroxide, oxide, sub-oxide, or a combination thereof. As used herein the terms “sub-oxide,” “sub-nitride,” or “sub-sulfide” is intended to connote a composition containing an amount reflecting a sub-stoichiometric or a mixed oxidation state of the M metal at the surface of oxide, nitride, or sulfide, respectively. For example, various forms of titania are known to exist as TiOₓ, where x can be less than 2. Accordingly, the surfaces of the present invention may also contain oxides, nitrides, or sulfides in similar sub-stoichiometric or mixed oxidation state amounts.

In the methods, these two-dimensional (2D) transition metal carbides may comprise simple individual layers, a plurality of stacked layers, or a combination thereof. They may contain intercalated ions, such as lithium ions, or other small molecules. Each layer may independently comprise surfaces functionalized by any of the surface coating features described herein (e.g., as in alkoxide, carboxylate, halide, hydroxide, hydride, oxide, sub-oxide, nitride, sub-nitride, sulfide, thiol, or a combination thereof) or may be also partially or completely functionalized by polymers, either on the surface of individual layers, for example, where the two-dimensional compositions are embedded within a polymer matrix, or the polymers may be intercalated between layers to form structural composites, or both. In certain embodiments, then, the EMI shielding coating comprises a polymer composite, the composite comprising one or more organic polymers or copolymers, such as are described elsewhere herein. These one or more polymers and copolymers include liquid crystalline (co)polymers (i.e., capable of arranging themselves in planar arrays by virtue of aromatic or polyaromatic features, and/or may comprise one or more, preferably a plurality of, oxygen-containing functional groups (e.g., —OH and/or —COOH) and/or amine-containing functional groups and/or thiol-containing functional groups (such as described herein), wherein the oxygen-containing functional groups (—OH, —COO, and ═O) and/or amine-containing functional groups and/or thiol are bonded (or capable of bonding) with the surface functionalities of the two-dimensional transition metal carbide materials.

For example, flakes of the two-dimensional transition metal carbides can be embedded in polymer matrices to make their films mechanically more robust and to further improve the oxidation resistance of these metal carbides. As an example, a Ti₃C₂-sodium alginate (SA) composite was formulated and its EMI shielding was tested, resulting in very high EMI shielding values. At about 90 wt. % Ti₃C₂ and 10 wt. % SA and a total film thickness of about 6 μm, the composite had about 3 times better EMI shielding capability than a pure 8.4 μm rGO. In all the previous reports on other nanomaterials, using a polymer as the matrix induced flexibility but reduced both conductivities and EMI shielding capabilities, which is clearly not the case for the present materials. Such a high EMI shielding has never been reported for any nanomaterial-polymer composite.

In some embodiments, the polymer composite comprises organic polymers, more specifically thermoset or thermoplastic polymers or polymer resins, elastomers, or mixtures thereof. Various embodiments include those wherein the polymer or polymer resin contains an aromatic or heteroaromatic moiety, for example, phenyl, biphenyl, pyridinyl, bipyridinyl, naphthyl, pyrimidinyl, including derivative amides or esters of terephthalic acid or naphthalic acid. Other embodiments provide that the polymer or polymer resin comprises polyester, polyamide, polyethylene, polypropylene, polyethylenenaphthalate (PEN), polyethylene terephthalate (PET), polybutylene terephthalate (PBT), polyether etherketone (PEEK), polyamide, polyaryletherketone (PAEK), polyethersulfone (PES), polyethylenenimine (PEI), poly (p-phenylene sulfide) (PPS), polyvinyl chloride (PVC), fluorinated or perfluorinated polymer (such as a polytetrafluoroethylene (PTFE or TEFLON™), polyvinylidene difluoride (PVDF), a polyvinyl fluoride (PVF or TEDLAR™)) (TEFLON™ and TEDLAR™ are registered trademarks of the E.I. DuPont de Nemours Company, of Wilmington, Del.)

The planar nature of MXene layers may be well suited to organizing themselves in those anisotropic polymers, for example having planar moieties, e.g., aromatic moieties, especially when (but not only when) these planar organic moieties are directionally oriented to be parallel in a polymer composite composition. Such embodiments include the inclusion of MXene compositions into liquid crystal polymers. Moreover, the ability to produce MXene compositions having both hydrophobic and hydrophilic pendants provides for compatibility with a wide-ranging variety of polymer materials.

Additional embodiments of the present invention provide polymer composites, including those wherein the polymer composite is in a form having a planar configuration—for example, a film, sheet, or ribbon—comprising a MXene layer or multilayer composition. Still further embodiments provide such polymer composites wherein the two-dimensional crystal layers of the MXene materials are aligned or substantially aligned with the plane of a polymer composite film, sheet, or ribbon, especially when the organic polymers are oriented in the plane of that film, sheet, or ribbon.

Natural biomaterials are also potentially ideal candidates for polymeric matrices since they are abundant, environmentally friendly, and mechanically robust. Sodium alginate (SA), a linear anionic polysaccharide copolymer derived from seaweed, consists of two different repeating units possessing massive oxygen-containing functional groups (—OH, —COO, and ═O). This material is water-like in its H-bonding ability and will have strong covalent bonds between the H-bonding-capable repeating units. In terms of molecular design, the molecular structure of SA is more similar to that of the chitin in the organic phase of natural nacre. When incorporated into a composite as a binder, sodium alginate has been shown to improve electrochemical performance as well as improving overall mechanical properties. For Li-ion battery applications, introducing small sodium alginate content as a binder, resulted in prolonged stability of Si electrodes during lithiation as well as increasing ion intercalation capacity as compared to other binders. Other polyfunctional polymers are expected to perform similarly.

Other polymeric materials containing these types of binding units and which are expected to be suitable include aliphatic polyesters, poly(amino acids), copoly(ether-esters), polyalkylene oxalates, polyoxaesters containing amine groups, poly(anhydrides), biosynthetic polymers based on sequences found in collagen, elastin, thrombin, fibronectin, starches, poly(amino acid), poly(propylene fumarate), gelatin, alginate, pectin, fibrin, oxidized cellulose, chitin, chitosan, tropoelastin, hyaluronic acid, poly(vinyl alcohol), ribonucleic acids, deoxyribonucleic acids, polypeptides, proteins, polysaccharides, polynucleotides and combinations thereof, polylactic acid (PLA), polyglycolic acid (PGA), polycaprolactone (PCL), poly(Lactide-co-Glycolide) (PLGA), polydioxanone (PDO), alginate or alginic acid or acid salt, chitosan polymers, or copolymers or mixtures thereof, PLA-PEG, PEGT-PBT, PLA-PGA, PEG-PCL, PCL-PLA, and functionalized poly(β-amino esters). Similarly, the polymer may be comprised of a mixture one or more natural, synthetic, biocompatible, biodegradable, non-biodegradable, and/or biosorbable polymers and co-polymers. Without being bound by any particular the correctness of any particular theory, it is believed that these polyfunctional groups are capable of at least hydrogen bonding, if not covalently bonding with the terminal surface functionalities of the two-dimensional carbide, nitride, or carbonitride materials.

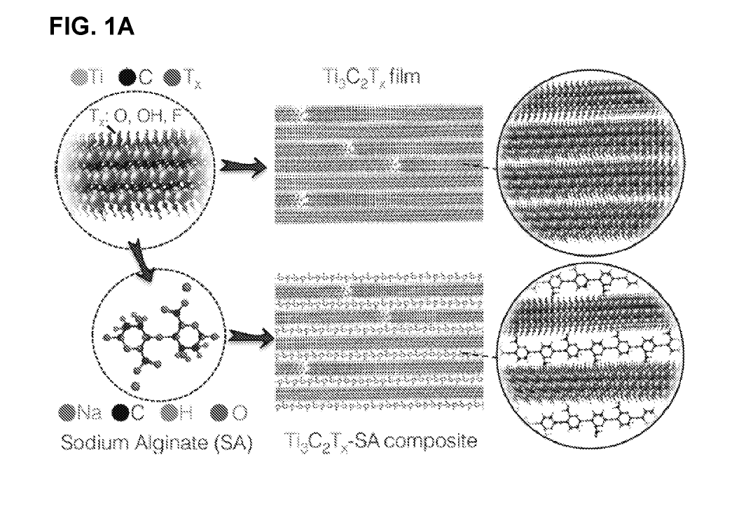

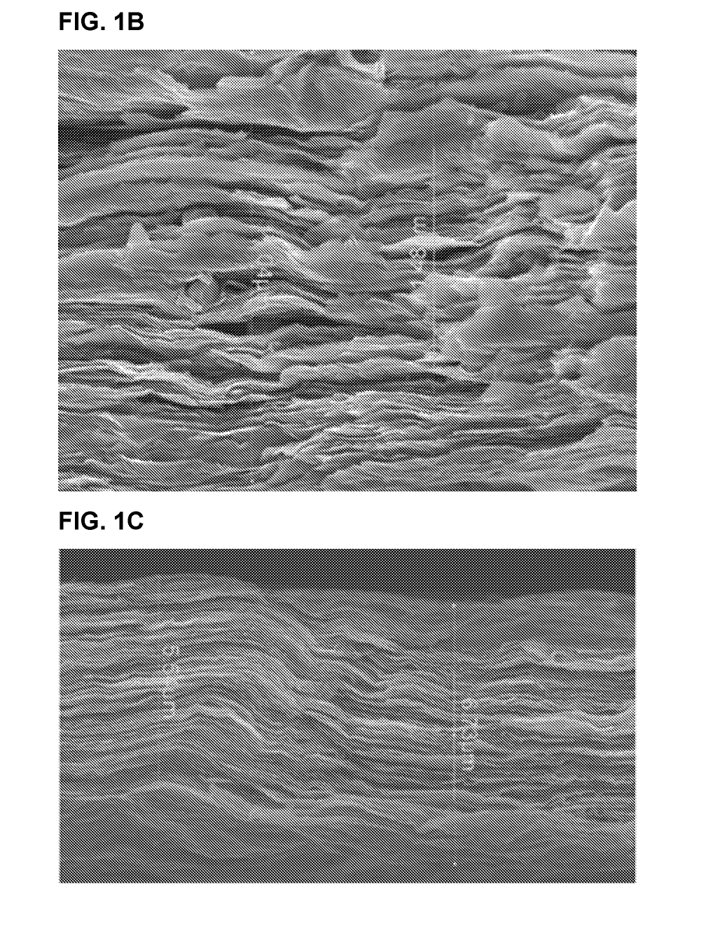

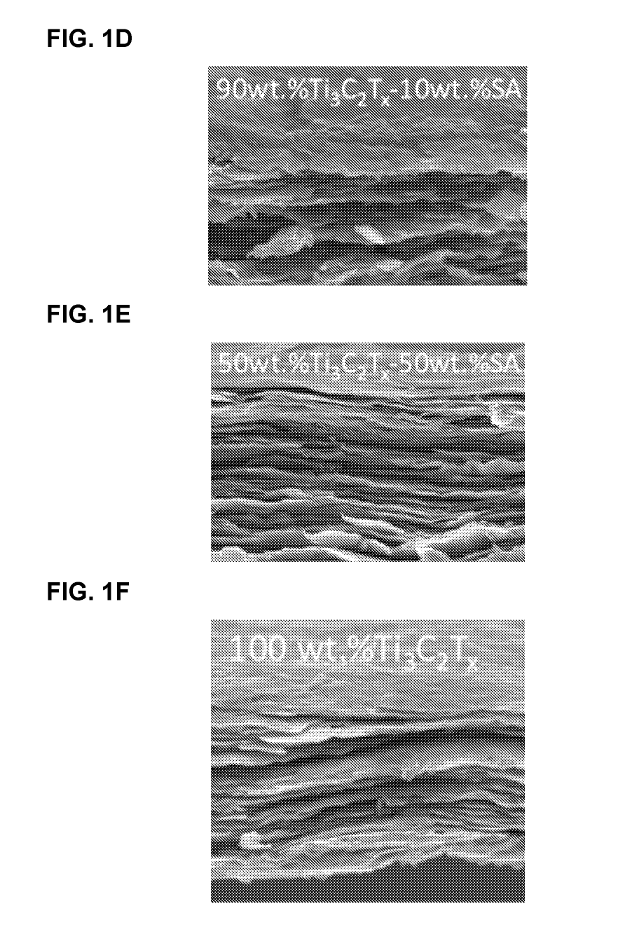

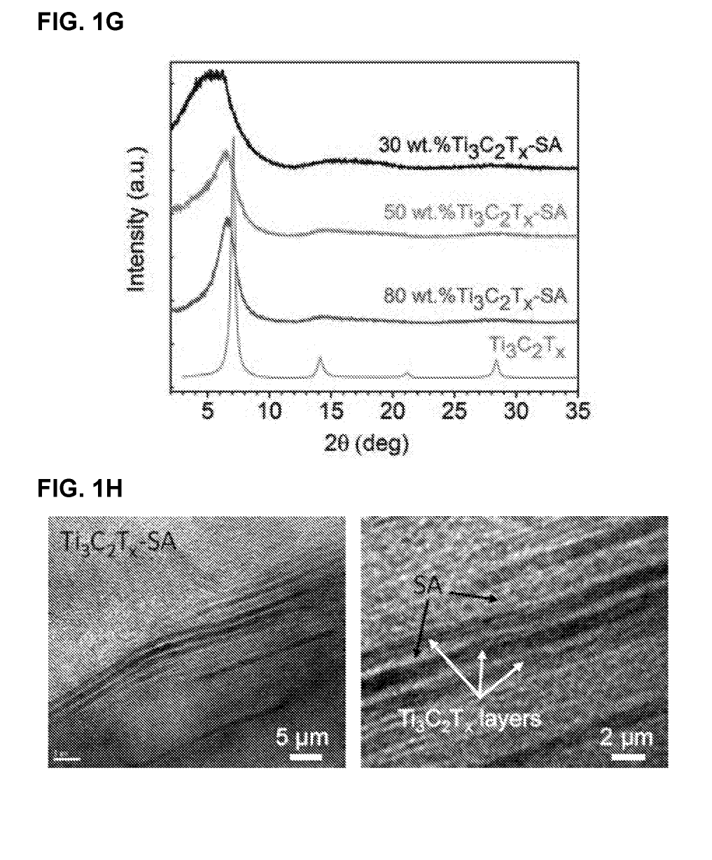

Bonded composite compositions comprising these two-dimensional materials, whose surface functionalities can be or are bonded together by polymers and copolymers comprising oxygen-containing functional groups (—OH, —COO, and ═O) and amine functional groups are also considered within the scope of the present disclosure. Such polymers and copolymers are described herein. Exemplary bonding arrangements are shown in FIG. 1A for the Ti₃C₂Tₓ-sodium alginate composite.

In other embodiments, the coating comprise an inorganic composite comprising a glass embedded or coated with any of the two-dimensional transition metal carbides, nitride, or carbonitrides described herein. Silicate, including borosilicate or aluminosilicate, glasses or clays may be useful for such purposes. Preferably, whether the composite is organic or inorganic, or a combination thereof, the substantially two-dimensional array of crystal cells defines a plane, and said plane is substantially aligned with the plane of the composite.

These coatings may be prepared, for example, by spincoating, dipcoating, printing, or compression molding of dispersions comprising the two-dimensional transition metal carbides. Typically, the dispersions are prepared in aqueous or organic solvents. In addition to the presence of the MXene materials, aqueous dispersions may also contain processing aids, such as surfactants, or ionic materials, for example lithium salt or other intercalating or intercalatable materials. If organic solvents are used, polar solvents are especially useful, including alcohols, amides, amines, or sulfoxides, for example comprising ethanol, isopropanol, dimethylacetamide, dimethylformamide, pyridine, and/or dimethylsulfoxide.

It is convenient to apply the dispersions by any number of industry recognized methods for depositing thin coatings on substrates, depending on the viscosity of the dispersion. This viscosity may depend on the concentration of two-dimensional transition metal carbides particles or sheets in the dispersion, as well as the presence and concentrations of other constituents. For example, at concentrations of between 0.001 and 100 mg/mL, it is convenient to apply the two-dimensional transition metal carbides to the substrate surface by spin coating. In some embodiments, these dispersions are applied dropwise onto the an optionally rotating substrate surface, during or after which the substrate surface is made to rotate at a rate in a range of from about 300 rpm (rotations per minute) to about 5000 rpm. Rotational speed depends on a number of parameters, including viscosity of dispersion, volatility of the solvent, and substrate temperature as are understood by those skilled in the art.

Other embodiments provide that the two-dimensional transition metal carbides dispersions are areally applied to the substrate surface (i.e., over an extended area of the substrate), for example by brushing, dipcoating, spray coating, or doctor blading. These films may be allowed to settle (self-level) as stationary films, but in other embodiments, these brushed, dipcoated, or doctor bladed films may be also subjected to rotating the substrate surface at a rate in a range of from about 300 rpm to about 5000 rpm. Depending on the character of the dispersions, this may be used to level or thin the coatings, or both.

Once applied, at least a portion of the solvent is removed or lost by evaporation. The conditions for this step obviously depend on the nature of the solvent, the spinning rate and temperature of the dispersion and substrate, but typically convenient temperatures include those in a range of from about 10° C. to about 300° C., though processing these coatings is not limited to these temperatures.

Additional embodiments provide that multiple coatings may be applied, that that the resulting coated film comprises an overlapping array of two or more overlapping layers of the two dimensional carbide platelets oriented to be essentially coplanar with the substrate surface.

Similarly, the methods are versatile with respect to substrates. Rigid or flexible substrates may be used. Substrate surfaces may be organic, inorganic, or metallic, and comprise metals (Ag, Au, Cu, Pd, Pt) or metalloids; conductive or non-conductive metal oxides (e.g., SiO₂, ITO), nitrides, or carbides; semi-conductors (e.g., Si, GaAs, InP); glasses, including silica or boron-based glasses; liquid crystalline materials; or organic polymers. Exemplary substrates include metallized substrates; oxidizes silicon wafers; transparent conducting oxides such as indium tin oxide, fluorine doped tin oxide, aluminum-doped zinc-oxide (AZO), indium-doped cadmium-oxide, or aluminum, gallium or indium-doped zinc oxide (AZO, GZO or IZO); photoresists or other organic polymers. These coatings may be applied to flexible substrates as well, including organic polymer materials. Exemplary organic polymers include those comprising polyetherimide, polyetherketone, polyetheretherketone, polyamide; exemplary liquid crystal materials include, for example, poly(3,4-ethylenedioxythiophene) [PEDOT] and its derivatives; organic materials can also be photosensitive photoresists

In certain embodiments, the organic or inorganic matrix materials and the two-dimensional transition metal carbides are present in a weight ratio range of from 2:98 to 5:95, from 5:95 to 10:90, from 10:90 to 20:80, from 20:80 to 30:70, from 30:70 to 40:60, from 40:60 to 50:50, from 50:50 to 60:40, from 60:40 to 70:30, from 70:30 to 80:20, from 80:20 to 90:10, from 90:10 to 95:5, from 95:5 to 98:2, or a range combining two or more of these ranges.

In certain embodiments, the coating comprising a two-dimensional transitional metal carbide composition has an electrically conductive or semi-conductive surface, preferably having a surface conductivity of at least 250 S/cm, at least 2500 S/cm, or at least 4500 S/cm (to about 5000 S/cm). In some embodiments, the coatings can exhibit surface conductivities in a range of from about 100 to 500 S/cm, from 500 to 1000 S/cm, from 1000 to 2000 S/cm, from 2000 to 3000 S/cm, from 3000 to 4000 S/cm, from 4000 to 5000 S/cm, from 5000 to 6000 S/cm, from 6000 to 7000 S/cm, from 7000 to 8000 S/cm, or any combination of two or more of these ranges. Such conductivities may be seen on flat or flexed substrates.

The coatings exhibit complex dielectric permittivities having real and imaginary parts. As normally found for such complex permittivities, those of the present coatings are a complicated function of frequency, ω, since it is a superimposed description of dispersion phenomena occurring at multiple frequencies.

Independently, the coating, whether comprising simple layers, stacked layers, or organic or inorganic composites can have a thickness in a range of from about 100 to 1000 Angstroms, 0.1 to 0.5 microns, 0.5 to 1 microns, 1 to 2 microns, 2 to 3 microns, 3 to 4 microns, 4 to 5 microns, 5 to 6 microns, 6 to 8 microns, 8 to 10 microns, 10 to 12 microns, or a range combining any two or more of these ranges.

In other independent embodiments, the coating exhibits a EMI shielding, over a frequency range of from 8 to 13 GHz, in a range of from 10 to 15 dB, from 15 to 20 dB, from 20 to 25 dB, from 25 to 30 dB, from 30 to 35 dB, from 35 to 40 dB, from 40 to 45 dB, from 45 to 50 dB, from 50 to 55 dB, from 55 to 60 dB, from 60 to 65 dB, from 65 to 70 dB, from 70 to 75 dB, from 75 to 80 dB, from 80 to 85 dB, from 85 to 90 dB, from 90 to 95 dB or a range combining any two or more of these ranges.

In still other embodiments, the coatings exhibit a figure of merit, described as SSE/t (in dB cm² g⁻¹) of a least 1000, at least 5000, at least 10,000 up to about 100,000. The specific parameters and methods of measuring this figure of merit is described in the Examples.

The Examples provide measured EMI shielding properties of three types of MXenes as examples of the potential of these metal carbides for this application. For instance, a Ti₃C₂ MXene film at about 11 μm thickness had three times higher EMI shielding values than that of a reduced graphene oxide (rGO) films at almost the same thicknesses. More examples are likewise available. In addition, to explore the potential of other members of the two-dimensional metal carbide family, two of the least conductive MXenes, Mo₂TiC₂ and Mo₂Ti₂C₃ were also tested and they both showed higher EMI shielding than graphene based shielding materials. Without intending to be bound by the correctness of any particular theory, the enhanced EMI shielding effectiveness is believed to results from a combination of the dipole nature of the surface functionality, the surface conductivity, and the layered crystalline nature of these two-dimensional transition metal carbide, nitride, or carbonitride materials.

### Terms

In the present disclosure the singular forms “a,” “an,” and “the” include the plural reference, and reference to a particular numerical value includes at least that particular value, unless the context clearly indicates otherwise. Thus, for example, a reference to “a material” is a reference to at least one of such materials and equivalents thereof known to those skilled in the art.

When a value is expressed as an approximation by use of the descriptor “about,” it will be understood that the particular value forms another embodiment. In general, use of the term “about” indicates approximations that can vary depending on the desired properties sought to be obtained by the disclosed subject matter and is to be interpreted in the specific context in which it is used, based on its function. The person skilled in the art will be able to interpret this as a matter of routine. In some cases, the number of significant figures used for a particular value may be one non-limiting method of determining the extent of the word “about.” In other cases, the gradations used in a series of values may be used to determine the intended range available to the term “about” for each value. Where present, all ranges are inclusive and combinable. That is, references to values stated in ranges include every value within that range.

It is to be appreciated that certain features of the invention which are, for clarity, described herein in the context of separate embodiments, may also be provided in combination in a single embodiment. That is, unless obviously incompatible or specifically excluded, each individual embodiment is deemed to be combinable with any other embodiment(s) and such a combination is considered to be another embodiment. Conversely, various features of the invention that are, for brevity, described in the context of a single embodiment, may also be provided separately or in any sub-combination. Finally, while an embodiment may be described as part of a series of steps or part of a more general structure, each said step may also be considered an independent embodiment in itself, combinable with others.

The transitional terms “comprising,” “consisting essentially of” and “consisting” are intended to connote their generally in accepted meanings in the patent vernacular; that is, (i) “comprising,” which is synonymous with “including,” “containing,” or “characterized by,” is inclusive or open-ended and does not exclude additional, unrecited elements or method steps; (ii) “consisting of” excludes any element, step, or ingredient not specified in the claim; and (iii) “consisting essentially of” limits the scope of a claim to the specified materials or steps and those that do not materially affect the basic and novel characteristic(s) of the claimed invention. Embodiments described in terms of the phrase “comprising” (or its equivalents), also provide, as embodiments, those which are independently described in terms of “consisting of” and “consisting essentially of” For those composition embodiments provided in terms of “consisting essentially of” the basic and novel characteristic(s) is the ability to provide EMI shielding effectiveness at levels described herein or as explicitly specified.

When a list is presented, unless stated otherwise, it is to be understood that each individual element of that list, and every combination of that list, is a separate embodiment. For example, a list of embodiments presented as “A, B, or C” is to be interpreted as including the embodiments, “A,” “B,” “C,” “A or B,” “A or C,” “B or C,” or “A, B, or C.” Similarly, a designation such as C₁₋₃ includes not only C₁₋₃, but also C₁, C₂, C₃, C₁₋₂, C₂₋₃, and C_{1,3}, as separate embodiments.

Throughout this specification, words are to be afforded their normal meaning, as would be understood by those skilled in the relevant art. However, so as to avoid misunderstanding, the meanings of certain terms will be specifically defined or clarified.

The term “two-dimensional (2D) crystalline transition metal carbides” or two-dimensional (2D) transition metal carbides” may be used interchangeably to refer collectively to compositions described herein as comprising substantially two-dimensional crystal lattices of the general formulae Mₙ₊₁Xₙ(Tₛ), M₂A₂X(Tₛ). and M′₂M″ₙXₙ₊₁(Tₛ), where M, M′, M″, A, X, and Tₛ are defined herein. Supplementing the descriptions herein, Mₙ₊₁Xₙ(Tₛ) (including M′₂M″ₘXₘ₊₁(Tₛ) compositions) may be viewed as comprising free standing and stacked assemblies of two dimensional crystalline solids. Collectively, such compositions are referred to herein as “Mₙ₊₁Xₙ(Tₛ),” “MXene,” “MXene compositions,” or “MXene materials.” Additionally, these terms “Mₙ₊₁Xₙ(Tₛ),” “MXene,” “MXene compositions,” or “MXene materials” can also independently refer to those compositions derived by the chemical exfoliation of MAX phase materials, whether these compositions are present as free-standing 2-dimensional or stacked assemblies (as described further below). These compositions may be comprised of individual or a plurality of such layers. In some embodiments, the MXenes comprising stacked assemblies may be capable of, or have atoms, ions, or molecules, that are intercalated between at least some of the layers. In other embodiments, these atoms or ions are lithium. In still other embodiments, these structures are part of an energy-storing device, such as a battery or supercapacitor.

The term “crystalline compositions comprising at least one layer having first and second surfaces, each layer comprising a substantially two-dimensional array of crystal cells” refers to the unique character of these materials. For purposes of visualization, the two-dimensional array of crystal cells may be viewed as an array of cells extending in an x-y plane, with the z-axis defining the thickness of the composition, without any restrictions as to the absolute orientation of that plane or axes. It is preferred that the at least one layer having first and second surfaces contain but a single two-dimensional array of crystal cells (that is, the z-dimension is defined by the dimension of approximately one crystal cell), such that the planar surfaces of said cell array defines the surface of the layer; it should be appreciated that real compositions may contain portions having more than single crystal cell thicknesses.

That is, as used herein, “a substantially two-dimensional array of crystal cells” refers to an array which preferably includes a lateral (in x-y dimension) array of crystals having a thickness of a single unit cell, such that the top and bottom surfaces of the array are available for chemical modification.

The following listing of Embodiments is intended to complement, rather than displace or supersede, the previous descriptions.

### Embodiment 1

A method for shielding an object from electromagnetic interference comprising superposing at least one surface of the object (i.e., contacting or non-contacting the surface) with a coating comprising a two-dimensional transitional metal carbide, nitride, or carbonitride composition having electrically conductive surfaces.

### Embodiment 2

The method of Embodiment 1, wherein the two-dimensional transition metal carbide, nitride, or carbonitride is a MX-ene composition.

### Embodiment 3

The method of Embodiment 1 or 2, wherein the two-dimensional transition metal carbide, nitride, or carbonitride comprises a composition comprising at least one layer having first and second surfaces, each layer comprising:

a substantially two-dimensional array of crystal cells,

each crystal cell having an empirical formula of Mₙ₊₁Xₙ, such that each X is positioned within an octahedral array of M,

wherein M is at least one Group IIIB, IVB, VB, or VIB metal,

wherein each X is C, N, or a combination thereof;

n=1, 2, or 3.

### Embodiment 4

The method of Embodiment 3 or 4, comprising a plurality of stacked layers.

### Embodiment 5

The method of any one of Embodiments 3 to 5, wherein at least one of said surfaces of each layer has surface terminations comprising alkoxide, carboxylate, halide, hydroxide, hydride, oxide, sub-oxide, nitride, sub-nitride, sulfide, thiol, or a combination thereof.

### Embodiment 6

The method of any one of Embodiments 3 to 6, wherein at least one of said surfaces of each layer has surface terminations comprising alkoxide, fluoride, hydroxide, oxide, sub-oxide, or a combination thereof.

### Embodiment 7

The method of any one of Embodiments 3 to 7, wherein both surfaces of each layer have said surface terminations comprising alkoxide, fluoride, hydroxide, oxide, sub-oxide, or a combination thereof.

### Embodiment 8

The method of any one of Embodiments 3 to 8, wherein M is at least one Group IVB, Group VB, or Group VIB metal, preferably Sc, Y, Lu, Ti, Zr, Hf, V, Nb, Ta, Cr, Mo, W, or more preferably Ti, Nb, V, or Ta.

### Embodiment 9

The method of any one of Embodiments 3 to 9, wherein M is Ti, and n is 1 or 2.

### Embodiment 10

The method of Embodiment 1, wherein the two-dimensional transition metal carbide, nitride, or carbonitride comprises a composition comprising at least one layer having first and second surfaces, each layer comprising:

a substantially two-dimensional array of crystal cells,

each crystal cell having an empirical formula of M′₂M″ₙXₙ₊₁, such that each X is positioned within an octahedral array of M′ and M″, and where M″ₙ are present as individual two-dimensional array of atoms intercalated (sandwiched) between a pair of two-dimensional arrays of M′ atoms,

wherein M′ and M″ are different Group IIIB, IVB, VB, or VIB metals (especially where M′ and M″ are Sc, Y, Lu, Ti, Zr, Hf, V, Nb, Ta, Cr, Mo, W, more preferably Ti, V, Nb, Ta, Cr, Mo, or a combination thereof),

wherein each X is C, N, or a combination thereof; and

n=1 or 2.

### Embodiment 11

The method of Embodiment 10, wherein n is 1, M′ is Mo, and M″ is Nb, Ta, Ti, or V, or a combination thereof.

### Embodiment 12

The method of Embodiment 10 or 11, wherein n is 2, M′ is Mo, Ti, V, or a combination thereof, and M″ is Cr, Nb, Ta, Ti, or V, or a combination thereof.

### Embodiment 13

The method of any one of Embodiments 10 to 12, wherein M′₂M″ₙXₙ₊₁ comprises Mo₂TiC₂, Mo₂VC₂, Mo₂TaC₂, Mo₂NbC₂, Mo₂Ti₂C₃, Cr₂TiC₂, Cr₂VC₂, Cr₂TaC₂, Cr₂NbC₂, Ti₂NbC₂, Ti₂TaC₂, V₂TaC₂, or V₂TiC₂, or their nitride or carbonitride analogs.

### Embodiment 14

The method of any one of Embodiments 10 to 13, wherein M′₂M″ₙXₙ₊₁, comprises Mo₂TiC₂, Mo₂VC₂, Mo₂TaC₂, or Mo₂NbC₂, or their nitride or carbonitride analogs.

### Embodiment 15

The method of any one of Embodiments 10 to 14, wherein M′₂M″ₙXₙ₊₁ comprises Mo₂Ti₂C₃, Mo₂V₂C₃, Mo₂Nb₂C₃, Mo₂Ta₂C₃, Cr₂Ti₂C₃, Cr₂V₂C₃, Cr₂Nb₂C₃, Cr₂Ta₂C₃, Nb₂Ta₂C₃, Ti₂Nb₂C₃, Ti₂Ta₂C₃, V₂Ta₂C₃, V₂Nb₂C₃, or V₂Ti₂C₃, or their nitride or carbonitride analogs.

### Embodiment 16

The method of any one of Embodiments 10 to 15, wherein M′₂M″ₙXₙ₊₁ comprises Mo₂Ti₂C₃, Mo₂V₂C₃, Mo₂Nb₂C₃, Mo₂Ta₂C₃, Ti₂Nb₂C₃, Ti₂Ta₂C₃, or V₂Ta₂C₃, or their nitride or carbonitride analogs.

### Embodiment 17

The method of any one of Embodiments 10 to 16, comprising a plurality of stacked layers.

### Embodiment 18

The method of any one of Embodiments 10 to 17, wherein at least one of said surfaces of each layer has surface terminations comprising alkoxide, carboxylate, halide, hydroxide, hydride, oxide, sub-oxide, nitride, sub-nitride, sulfide, thiol, or a combination thereof.

### Embodiment 19

The method of any one of Embodiments 10 to 18, wherein at least one of said surfaces of each layer has surface terminations comprising alkoxide, fluoride, hydroxide, oxide, sub-oxide, or a combination thereof.

### Embodiment 20

The method of any one of Embodiments 10 to 19, wherein both surfaces of each layer have said surface terminations comprising alkoxide, fluoride, hydroxide, oxide, sub-oxide, or a combination thereof.

### Embodiment 21

The method of Embodiment 1 or 2, wherein the two-dimensional transitional metal carbide, nitride, or carbonitride composition comprises any composition described in U.S. patent application Ser. No. 14/094,966, filed Dec. 3, 2013, or its predecessors.

### Embodiment 22

The method of Embodiment 1 or 2, wherein the two-dimensional transitional metal carbide, nitride, or carbonitride composition comprises any composition described in PCT/US2015/051588, filed Sep. 23, 2015, or its predecessors.

### Embodiment 23

The method of Embodiment 1 or 2, wherein the two-dimensional transitional metal carbide, nitride, or carbonitride composition comprises any composition described in PCT/US2016/028354, filed Apr. 20, 2016, or its predecessors.

### Embodiment 24

The method of Embodiment 1, wherein the coating comprising a polymer composite comprising an organic polymer, including for example, a polysaccharide polymer, preferably an alginate or modified polymer (or any of the polymers described herein), and the two-dimensional transition metal carbide, nitride, or carbonitride of any one of Embodiments 1 to 32, wherein the polymers/copolymers and the two-dimensional transition metal carbide, nitride, or carbonitride material are present in a weight ratio range of from 2:98 to 5:95, from 5:95 to 10:90, from 10:90 to 20:80, from 20:80 to 30:70, from 30:70 to 40:60, from 40:60 to 50:50, from 50:50 to 60:40, from 60:40 to 70:30, from 70:30 to 80:20, from 80:20 to 90:10, from 90:10 to 95:5, from 95:5 to 98:2, or a range combining two or more of these ranges.

### Embodiment 25

The method of Embodiment 24, wherein the substantially two-dimensional array of crystal cells defines a plane, and said plane is substantially aligned with the plane of the polymer composite.

### Embodiment 26

The method of Embodiment 1, wherein the coating comprising an inorganic composite comprising a glass embedded or coated with the two-dimensional transition metal carbide, nitride, or carbonitride of any one of claims 1 to 32.

### Embodiment 27

The method of any one of Embodiments 1 to 26, wherein coating comprising a two-dimensional transitional metal carbide, nitride, or carbonitride composition has an electrically conductive or semi-conductive surface, preferably having a surface conductivity of at least 250 S/cm, 2500 S/cm, or at least about 4500 S/cm (to about 8000 S/cm.

### Embodiment 28

The method of Embodiment 27, wherein coating has a thickness in a range of from about 2 to 3 microns, 3 to 4 microns, 4 to 5 microns, 5 to 6 microns, 6 to 8 microns, 8 to 10 microns, 10 to 12 microns, or greater (e.g., to 1 mm), or a range combining any two or more of these ranges.

### Embodiment 29

The method of any one of Embodiments 1 to 28, wherein the coating exhibits a EMI shielding, over a frequency range of from 8 to 13 GHz, in a range of from 10 to 15 dB, from 15 to 20 dB, from 20 to 25 dB, from 25 to 30 dB, from 30 to 35 dB, from 35 to 40 dB, from 40 to 45 dB, from 45 to 50 dB, from 50 to 55 dB, from 55 to 60 dB, from 60 to 65 dB, from 65 to 70 dB, from 70 to 75 dB, from 75 to 80 dB, from 80 to 85 dB, from 85 to 90 dB, from 90 to 95 dB or a range combining any two or more of these ranges. In certain Aspects of these Embodiments, the coatings exhibit a figure of merit, described as SSE/t (in dB cm² g⁻¹), of a least 1000, at least 5000, at least 10,000 up to about 100,000.

### Embodiment 30

A bonded composite composition coating comprising any one or more of the two-dimensional transition metal carbide, nitride, or carbonitride materials described herein and one or more polymers and copolymers comprising oxygen-containing functional groups (e.g., —OH and/or —COOH) and/or amine-containing functional groups and/or thiol-containing functional groups (such as described herein), wherein the oxygen-containing functional groups (—OH, —COO, and ═O) and/or amine-containing functional groups and/or thiol are bonded (or capable of bonding) with the surface functionalities of the two-dimensional transition metal carbide materials, and wherein the polymers/copolymers and two-dimensional transition metal carbide, nitride, or carbonitride material are present in a weight ratio range of from 2:98 to 5:95, from 5:95 to 10:90, from 10:90 to 20:80, from 20:80 to 30:70, from 30:70 to 40:60, from 40:60 to 50:50, from 50:50 to 60:40, from 60:40 to 70:30, from 70:30 to 80:20, from 80:20 to 90:10, from 90:10 to 95:5, from 95:5 to 98:2, or a range combining two or more of these ranges.

### Embodiment 31

The bonded composite composition coating of Embodiment 30, that exhibits an electrically conductive or semi-conductive surface, preferably having a surface conductivity of at least 250 S/cm, 2500 S/cm, or 4500 S/cm to about 8000 S/cm.

### Embodiment 32

The bonded composite composition coating of Embodiment 30 or 310, having a thickness in a range of from about 2 to 3 microns, 3 to 4 microns, 4 to 5 microns, 5 to 6 microns, 6 to 8 microns, 8 to 10 microns, 10 to 12 microns, or a range combining any two or more of these ranges.

### Embodiment 33

The bonded composite composition coating of any one of Embodiment 30 to 32, that exhibits a EMI shielding, over a frequency range of from 8 to 13 GHz, in a range of from 10 to 15 dB, from 15 to 20 dB, from 20 to 25 dB, from 25 to 30 dB, from 30 to 35 dB, from 35 to 40 dB, from 40 to 45 dB, from 45 to 50 dB, from 50 to 55 dB, from 55 to 60 dB, from 60 to 65 dB, from 65 to 70 dB, from 70 to 75 dB, from 75 to 80 dB, from 80 to 85 dB, from 85 to 90 dB, from 90 to 95 dB or a range combining any two or more of these ranges.

### Embodiment 34

The bonded composite composition coating of any one of Embodiment 30 to 33 having a figure of merit, described as SEE/t (in dB cm² g⁻¹), of a least 1000, at least 5000, at least 10,000 up to about 100,000. The specific parameters and methods of measuring this figure of merit is described in the Examples.

### EXAMPLES

The following Examples are provided to illustrate some of the concepts described within this disclosure. While each Example is considered to provide specific individual embodiments of composition, methods of preparation and use, none of the Examples should be considered to limit the more general embodiments described herein. In particular, while the examples provided here focus on specific MXene materials and alginate polymers, it is believed that the principles described are relevant to other such two-dimensional transition metal carbide materials. Accordingly, the descriptions provided here should not be construed to limit the disclosure, and the reader is advised to look to the nature of the claims as a broader description.

In the following examples, efforts have been made to ensure accuracy with respect to numbers used (e.g. amounts, temperature, etc.) but some experimental error and deviation should be accounted for. Unless indicated otherwise, temperature is in degrees C., pressure is at or near atmospheric.

### Example 1

### Example 1.1. Materials and Methods

Lithium fluoride (LiF, Alfa Aesar, 98.5%), hydrochloric acid (HCl, Fisher Scientific, 37.2%), hydrofluoric acid (HF, Acros Organics, 49.5 wt. %,), tetrabutylammonium hydroxide (TBAOH, Acros Organics, 40 wt % solution in water), and alginic acid sodium salt (sodium alginate, Sigma Aldrich) were used as received.

### Example 2.2. Materials Characterization

Morphology of the composite films was investigated by scanning electron microscopy (SEM) (Zeiss Supra 50VP, Germany). X-ray diffraction (XRD) was carried out using a Rigaku Smartlab (Tokyo, Japan) diffractometer with Cu-Kα radiation (40 kV and 44 mA); step scan 0.02°, 3°-70° 2 theta range, step time of 0.5 s, 10×10 mm² window slit. Sample structure was characterized using Transmission Electron Microscopy (TEM) (JEOL-2100, Japan) at an acceleration voltage of 200.0 kV.

Electromagnetic shielding measurements were carried out using Agilent Network Analyzer (ENA5071C in the 8.2-12.4 GHz (X-band) microwave range. Electrical conductivity of composite samples were measured using a four-pin probe (MCP-TP06P PSP) with Loresta GP meter (MCP-T610 model, Mitsubishi Chemical, Japan).

Morphology of the composite films was investigated by scanning electron microscopy (SEM) (Zeiss Supra 50VP, Germany). X-ray diffraction (XRD) analysis was carried out using a Rigaku Smartlab (Tokyo, Japan) diffractometer with Cu-Kα radiation (40 kV and 44 mA); step scan 0.02°, 3°-70° 2 theta range, step time of 0.5 s, 10×10 mm² window slit. Sample structure was characterized using Transmission Electron Microscopy (TEM) (JEOL-2100, Japan) at an acceleration voltage of 200.0 kV.

Electromagnetic interference shielding measurements of pristine as well as composite films were carried out in a WR-90 rectangular waveguide using a 2-port network analyzer (ENA5071C, Agilent Technologies, USA) in X-band frequency range (8.2-12.4 GHz). A standard procedure for calibrating the equipment was performed using short offset, short and load on both ports, 1 and 2. The samples were cut into a rectangular shape, slightly larger in dimension (25×12 mm²) as compared to the opening of the sample holder (22.84×10.14 mm²). Scotch tape was attached to one end of the film to mount it onto the sample holder. While mounting the film onto the sample holder, extra care was taken to avoid any leakage paths from the edges. The sample holder was tightly fixed with screws and springloaded clamps. The distance from sample to port 1 was set as 0, and the length of the sample holder was fixed as 140 mm. Electromagnetic wave has an incident power of 0 dB, which corresponds to 1 mW. Thickness of samples ranged from 1 μm to about 45 μm for different MXenes and composite films.

The low frequency EMI SE measurement (30 MHz-1.5 GHz) was performed in accordance with ASTM D4935-99 by using a standard enlarged coaxial transmission line sample holder. The reference and load samples for EMI testing were cut into the required shape from the laminated PET-Ti₃C₂Tₓ-PET sheet in accordance with ASTM specifications. The reference samples consisted of two pieces, a ring-shaped piece with outer and inner diameters of 133.1 mm and of 76.2 mm, respectively, and a circular piece having a diameter of 33.0 mm. The load sample was made by cutting the PET-Ti₃C₂Tₓ-PET sheet into a circular shape with an outer diameter of 133.1 mm. Double-sided tape was used to mount the reference and load samples in between the two halves of the sample holder. PET films, that are perfect insulators and transparent to EM radiation, showed ˜0 dB and did not affect the EMI SE of the laminated Ti₃C₂Tₓ film.

Electrical conductivity of all samples was measured using a linear four-pin probe (MCP-TP06P PSP) with a Loresta-GP meter (MCP-T610 model, Mitsubishi Chemical, Japan). Inter-pin distance of the probe was 1.5 mm and voltage at the open terminal was set as 10 V. Samples for electrical conductivity measurements were made by punching the MXene films with a 10 mm custom designed stainless steel cutter. Four-pin probe was placed at the center of the thin films and sheet resistance was recorded. Electrical conductivity of all the samples was calculated by the equation:

σ=(Rₛt)⁻¹, (1)

where σ is the electrical conductivity [S cm⁻¹], Rₛ is the sheet resistance [Ω sq⁻¹] and t is the thickness of samples [cm⁻¹]. Thickness measurements were performed by using a highly accurate length gauge (±0.1 μm) of Heidenhain Instruments (Germany) and counter checked by the SEM technique. The density of pure MXene and composite samples was calculated from experimental measurements of the volume and mass of the samples.

The electromagnetic interference shielding effectiveness (EMI SE), is a measure of material's ability to block electromagnetic waves. For electrically conductive materials, theoretically, EMI SE can be represented by Simon formalism;

$$SE = 50 + 10 log ( \frac{σ}{f} ) + 1.7 t \sqrt{σ f} \qquad ( 2 )$$

where σ [S cm⁻¹] is the electrical conductivity, f [MHz] is the frequency and t [cm] is the thickness of shield. Thus EMI SE shows strong dependence on electrical conductivity and thickness of the shielding material. Experimentally, EMI SE was measured in decibels [dB] and defined as the logarithmic ratio of incoming power (PI) to transmitted power (PI) as

$$Shielding effectiveness SE ( dB ) = 10 log ( \frac{{P}_{I}}{{P}_{T}} ) \qquad ( 3 )$$

When an electromagnetic radiation is incident on shielding device, the reflection (R), absorption (A), and transmission (T) must add up to 1, that is,

R+A+T=1 (4)

The reflection (R) and transmission (T) coefficients were obtained from the network analyzer in form of scattering parameters, “Sₘₙ”, which measure how energy is scattered from a material or device. The first letter “m” designate the network analyzer port receiving the EMI radiation and the second letter “n”, represents the port that is transmitting the incident energy. Vector network analyzer directly gave the output in form of four scattering parameters (S11, S12, S21, S22), which could be used to find the R and T coefficients as:

R=|S₁₁|²=|S₂₂|² (5)

T=|S₁₂|²=|S₂₁|² (6)

The total EMI SE (EMI SE_{T}) is the sum of the contributions from reflection (SE_{R}), absorption (SE_{A}) and multiple internal reflections (SE_{MR}). At higher EMI SE values, and with a multilayer EMI shield (as in the case of MXenes), contribution from multiple internal reflection is merged in the absorption, because the re-reflected waves get absorbed or dissipated in form of heat in the shielding material. The total SET can be written as (8);

SE_{T}=SE_{R}+SE_{A} (7)

The effective absorbance (A_{eff}), a measure of the absorbed electromagnetic waves in a material can be described as:

$${A}_{eff} = ( \frac{1 - R - T}{1 - R} ) \qquad ( 8 )$$

SE_{R} and SE_{A} can be expressed in terms of reflection and effective absorption considering the power of the incident electromagnetic waves inside the shielding material as (8, 37):

$$\begin{matrix}{SE}_{R} = 10 log ( \frac{1}{1 - R} ) = 10 log ( \frac{1}{1 - {\vert {S}_{11} \vert}^{2}} ) & ( 9 ) \\ {SE}_{A} = 10 log ( \frac{1}{1 - {A}_{eff}} ) = 10 log ( \frac{1 - R}{T} ) = 10 log ( \frac{1 - {\vert {S}_{11} \vert}^{2}}{{\vert {S}_{21} \vert}^{2}} ) & ( 10 )\end{matrix}$$

Specific shielding effectiveness (SSE) was derived to compare the effectiveness of shielding materials taking into account the density. Lightweight materials (with low density), deliver high SSE. The SSE parameter is relative, and high values show more suitability of a particular material.

Mathematically, SSE can be obtained by dividing the EMI SE with density of material as follows:

SSE=EMI SE/density=dB cm³ g⁻¹ (11)

SSE has a basic limitation, that is, it does not account for the thickness information. Higher values of SSE could simply be obtained at large thickness while maintaining the low density. However, large thickness increases the net weight and is disadvantageous. To account for the thickness contribution, following equation is used to evaluate the absolute effectiveness (SSEt) of a material in relative terms:

SSEt=SSE/t=dB cm³ g⁻¹ cm⁻¹=dB cm² g⁻¹ (12)

EMI shielding efficiency presents the material ability to block waves in terms of percentage. For example, EMI SE of 10 dB corresponds to 90% blockage of incident radiation, 30 dB corresponds to 99.9% blockage of incident radiation, respectively. EMI shielding effectiveness [dB] is converted into EMI shielding efficiency [%] using the equation (2) as:

$$Shielding efficiency ( \% ) = 100 - ( \frac{1}{{10}^{\frac{SE}{10}}} ) \times 100 \qquad ( 13 )$$

### Example 1.3. Synthesis of Ti₃AlC₂ (MAX)

Ti₃AlC₂ was synthesized according to Naguib, M., et al., Two-Dimensional Nanocrystals Produced by Exfoliation of Ti₃AlC₂. Advanced Materials, 2011. 23(37): p. 4248-4253, and the powders were crushed and sieved through 400 mesh size (≤38 μm particle size) and collected for etching.

### Example 1.4. Minimally Intensive Layer Delamination (MILD) Synthesis of Ti₃C₂Tₓ

Ti₃C₂Tₓ was synthesized using an improved etching route according to method described in Ghidiu, M., et al., Conductive two-dimensional titanium carbide/clay/′ with high volumetric capacitance. Nature, 2014. 516(7529): p. 78-81. This is designated as MILD method, eliminating excessive processing previously needed for Ti₃C₂Tₓ delamination. Briefly, the etchant solution used in MILD method was prepared by dissolving 1 g LiF in 20 ml of 6M HCl in 100 ml-polypropylene plastic vial after which 1 g of Ti₃AlC₂ was gradually added to it and the reaction allowed to proceed for 24 h at 35° C. The acidic product was washed copiously with DI H₂O via centrifugation at 3500 rpm till pH ≥6 at which dark green supernatant solution of large Ti₃C₂Tₓ flakes can be collected after 1 h centrifugation at the same rpm. Up to 1.5 mg/ml of Ti₃C₂Tₓ colloidal solution were collected. This method, seen as an improvement over previous methods, is considered to be generally useful for forming MX-ene materials from MAX-phase materials. As such, these methods are separate embodiments of the present inventions.

### Example 1.5. Synthesis of Mo₂TiC₂Tₓ and Mo₂Ti₂C₃Tₓ

1 g of Mo₂TiAlC₂ was etched in 10 ml solution of 10 wt. % HF and 10 wt. % HCl at 40° C. for 40 h. The product was washed with DI H₂O until neutralized before being collected and dried in vacuum overnight. The collected Mo₂TiC₂Tₓ was stirred in 50 ml of H₂O containing 0.8 wt. % TBAOH for 2 h before collecting the colloidal solution via centrifugation after 1 h at 3500 rpm.

Mo₂Ti₂C₃Tₓ was synthesized by etching Mo₂Ti₂AlC₃ and delaminating the resulting product using the same or similar conditions as in synthesis of Mo₂TiAlC₂

### Example 1.6. Delamination of Mo₂TiC₂Tₓ and Mo₂Ti₂C₃Tₓ

1 g of Mo₂TiC₂Tₓ and 1 g Mo₂Ti₂C₃Tₓ were separately stirred in 50 ml of H₂O containing 0.8 wt. % TBAOH for 2 h before collecting the colloidal solution via centrifugation after 1 hour at 3500 rpm.

### Example 1.7. Ti₃C₂Tₓ LiF—HCl Solution Synthesis Method

Ti₃C₂Tₓ was synthesized by etching the “A” element of the corresponding MAX phase followed by exfoliation. Ti₃AlC₂ powder with average particle sized of ≤30 μm was treated using LiF—HCl solution. LiF powder was added to 9M HCl and magnetically stirred for 10 min. MAX phase powder was then slowly added to the previous solution, and the resultant mixture was then magnetically stirred at room temperature (RT) for 24 h. Resultant suspension was washed using deionized water (DI H₂O) and separated from remaining HF, Li⁺ ions, and Cl— ions by centrifuging. This was repeated six to seven times until the pH of the liquid reached approximately 5-6. The resultant sediment was dispersed in DI H₂O in wide-mouth jar and sonicated in an ice bath using Bransonic Ultrasonic Cleaner (Branson 2510) for 1 h under Argon (Ar) gas purging. The mixture was then centrifuged at 3500 rpm for 1 h to separate remaining multilayered Ti₃C₂Tₓ and unetched MAX phase. The delaminated Ti₃C₂Tₓ supernatant was then decanted and collected resulting in an aqueous colloidal Ti₃C₂Tₓ solution. The obtained Ti₃C₂Tₓ was stored in capped plastic containers with Ar purged headspaces and stored at RT conditions for future experiments.

### Example 1.8. Preparation of Ti₃C₂Tx/Sodium Alginate (SA) Composite Films

Pure Ti₃C₂Tₓ films and Ti₃C₂Tₓ/sodium alginate composite films were prepared using vacuum-assisted filtration (VAF). Such methods are generally applicable at least to the wide range of polymers described herein as useful composite materials. Desired composite film ratios were synthesized starting with respective aqueous solutions of Ti₃C₂Tₓ and SA. Aqueous SA solutions of 0.5 mg/mL were simply prepared by dissolving desired SA content into deionized water followed by bath sonication for 20-30 min until SA grains completely dissolved. Subsequently, colloidal Ti₃C₂Tₓ solution, based on desired final Ti₃C₂Tₓ content, was added to SA solution and the resultant mixture was then stirred for 24 hours at RT yielding a series of aqueous Ti₃C₂Tₓ/SA solutions with different Ti₃C₂Tₓ contents (90, 80, 60, 50, 30, 10 wt. %). Two sets of film thicknesses were prepared for each ratio with MXene content kept constant at 20 mg and 10 mg, respectively. Each aqueous Ti₃C₂Tₓ/SA solution was filtered using a porous Celgard membrane. Each VAF sample was allowed to filter until dry for 24-72 hours at RT. Pure Ti₃C₂Tₓ and SA films were filtered using the same method for comparison.

In separate experiments, Ti₃C₂Tₓ was synthesized following the MILD method explained earlier and washed for six to seven times until the pH of ˜5-6 via centrifugation. After decanting the supernatant, the swelled clay-like sediment was redispersed in DI H₂O in a wide-mouth jar and ultrasonicated in an ice bath using Bransonic Ultrasonic Cleaner (Branson 2510) for 1 h under Argon (Ar) gas purging. The mixture was then centrifuged at 3500 rpm for 1 h and the delaminated Ti₃C₂Tₓ supernatant was collected and stored for future experiments. An aqueous SA solution with concentration of 0.5 mg ml⁻¹ was prepared by completely dissolving desired SA content into deionized water. Subsequently, aqueous Ti₃C₂Tₓ colloidal solution, based on the desired final Ti₃C₂Tₓ content, was added to SA solution and resultant mixture was then stirred for 24 hours at RT yielding a series of aqueous Ti₃C₂Tₓ-SA solutions with different initial Ti₃C₂Tₓ contents (90, 80, 60, 50, 30, 10 wt. %). This corresponds to approximately 74, 55, 32, 24, 12, and 3 vol. % of Ti₃C₂Tₓ. Each aqueous Ti₃C₂Tₓ-SA solution was filtered using a polypropylene membrane (Celgard, pore size 0.064 μm). It is important to mention that the polymer content in the membranes may be lower than in the solution due to possibility of some of the polymer going through the filter, especially at lower MXene contents. However, this should not affect the observed trends. Each VAF sample was allowed to filter until dry for 24-72 hours at RT. Samples were designated as follows: for example, a 90 wt. % Ti₃C₂Tₓ with 10 wt. % SA will be referred to as 90 wt. % Ti₃C₂Tₓ-SA. Pure Ti₃C₂Tₓ film was filtered using the same method for comparison.

### Example 1.9. Preparation of Freestanding Films of Ti₃C₂Tₓ, Mo₂TiC₂Tₓ, Mo₂Ti₂C₃Tₓ, and Ti₃C₂Tₓ-SA Composites

All freestanding films were prepared via vacuum-assisted filtration (VAF) using Durapore filter membrane (polyvinyldifluoride PVDF, Hydrophilic, with 0.1 μm pore size) to make Ti₃C₂Tₓ, Mo₂TiC₂Tₓ, and Mo₂Ti₂C₃Tₓ, films and using Celgard filter membrane (polypropylene, pore size 0.064 μm) to make Ti3C2Tx-SA composite films. All films were allowed to dry at room temperature (RT) before being easily peeled off as freestanding films and stored under vacuum for future use.

### Example 1.10. Spray-Coated Ti₃C₂Tₓ Film on Polyethylene Terephthalate

A strong and large film is required to handle the heavy weight (˜13 kg) of ASTM coaxial sample holder used for EMI SE measurement at low frequencies. Accordingly, thin and large area Ti₃C₂Tₓ film (20×27 cm²) with thickness of ˜4 μm was prepared by spray coating an aqueous solution of Ti₃C₂Tₓ (10 mg/ml) on a 29×23 cm² PET flexible substrate, which was subjected to continuous drying using an air gun. The dried Ti₃C₂Tₓ film was subsequently laminated between PET sheets using a commercial laminator (Staples, multiuse laminator) resulting in a PET-Ti₃C₂Tₓ-PET sandwich-like structure. For control measurement, a plain PET sheet was laminated in a similar manner.

### Example 2.7. Structure Characterization of Ti₃C₂/Sodium Alginate Composite Films (SEM, XRD, TEM)

By incorporating MXene flakes in SA binder matrices, novel nacre-like composite with very high EMI shielding in the X-band frequency region were formed. Ti₃C₂Tₓ flakes were embedded in SA, by vacuum-assisted filtration of their colloidal solutions at various loadings. The schematic representation of the fabrication process of Ti₃C₂Tₓ/SA films is displayed in FIG. 1A. These composites exhibited the highest EMI shielding for composite materials. Composite films of varying content were produced. In this study, the morphology, structural, and conductive properties were also explored. SA was chosen as a binder for Ti₃C₂Tₓ flakes to help reduce the effects of oxidation which is a common problem for MXenes. For energy storage applications, SA as a binder has the ability to enhance Ti₃C₂Tₓ electrode stability and the potential to improvement ion intercalation capacity compared to other binders. Additionally, the added property of high EMI shielding increases functionality of MXene-binder composites.

The cross-sectional and top view scanning electron microscopy (SEM) image of the 90 wt. % Ti₃C₂Tₓ-SA, 50 wt. % Ti₃C₂Tₓ-SA and pristine Ti₃C₂Tₓ are shown in FIGS. 1B-1F. In all composite loadings, the nacre-like layered stacking of the Ti₃C₂Tₓ was kept and it is similar to 100% Ti₃C₂Tₓ films. This characteristic is also confirmed by the presence of the Ti₃C₂Tₓ (00l) peaks in the 30 wt. % Ti₃C₂Tₓ-SA XRD pattern (FIG. 1G). It is clear that the (002) is broader than that of the higher Ti₃C₂Tₓ contents, which is due to the presence of more SA in between the layers, which can add more to its disordered stacking. Also, the shift in the Ti₃C₂Tₓ (002) by increasing the SA content is due to the presence of SA in between the MXene flakes, which increased the interlayer spacing.

TEM image of the Ti₃C₂Tₓ-sodium alginate composite confirms the intercalation of SA in between each MXene flakes (FIG. 1H). Only single flakes of Ti₃C₂Tₓ are observed in the high SA contents, however, multilayered Ti₃C₂Tₓ are observed in the higher Ti₃C₂Tₓ content which can be due to their restacking during filtration. This can also explain their higher intensity of the (002) peaks.

### Example 2. Initial Results

### Example 2.1. Two-Dimensional Transition Metal Carbide Films; Initial Results

Three different MXene compositions Ti₃C₂, Mo₂TiC₂ and Mo₂Ti₂C₃, with different thicknesses were tested and their electrical conductivities are listed in Table 1. Three films of (Mo₂Ti₂C₃) with thickness of 2.2, 2.5, 3.5 μm were tested and their electrical conductivities lie in the range of 250˜350 S cm⁻¹. Five films of (Mo₂TiC₂) with thicknesses of 1, 1.8, 2.1, 2.5, 4 μm were tested and their electrical conductivities were measured to be in the range of 90˜150 S cm⁻¹. Similarly, four films of Ti₃C₂ with thicknesses of 1.5, 2.5, 6, 11.2 μm were tested and their electrical conductivities were also in the range of 4800˜5000 S cm⁻¹.

### Example 2.2. Two-Dimensional Transition Metal Carbide Composites

In order to make MXene films more mechanically strong and increase their flexibility, Ti₃C₂ MXene-polymer composite films were fabricated. Moreover, using a polymer as a matrix can further enhance MXenes oxidation resistance. Sodium alginate (SA) was chosen as an example to explore the EMI shielding properties of MXene-polymer composites. Two films of Ti₃C₂-SA with thicknesses of 2 and 6.5 μm were tested. Both composite films contained approximately 10 wt. % SA and their electrical conductivity lies in range of 2900˜3000 S·cm⁻¹.

A total of 17 MXene samples (films) were received in five pouches as mentioned in Table 1. Pouch #1 contains three films of (Mo₂Ti₂C₃) with thickness (2.2, 2.5, 3.5 μm). Electrical conductivity lies in range of 250˜350 S cm⁻¹. Pouch #2 contains five films of (Mo₂TiC₂) with thickness (1, 1.8, 2.1, 2.5, 4 μm). Electrical conductivity lies in range of 90˜150 S cm⁻¹. Pouch #3 contains two films of (Ti₃C₂/Composite) with thickness (2, 6.5 μm). Electrical conductivity lies in range of 2900˜3000 S cm⁻¹. Pouch #4 contains three films of (Ti₃C₂) with thickness (4.6, 4.8, 4.9 μm). Electrical conductivity lies in range of 4500˜5000 S cm⁻¹. Pouch #5 contains four films of (Ti₃C₂) with thickness (1.5, 2.5, 6, 11.2 μm). Electrical conductivity lies in range of 4800˜5000 S cm⁻¹.

TABLE 1
Electrical conductivity of different two-dimensional
transition metal carbide samples

| | Two-dimensional | | | |
|---|---|---|---|---|
| | transition | # of films | Thickness | |
| | metal carbide | tested | (μm) | Conductivity (S cm⁻¹) |
| 1 | Mo₂Ti₂C₃ | 3 | 2.2-3.5 | 2.5 × 10²~3.5 × 10² |
| 2 | Mo₂TiC₂ | 5 | 1-4 | 9.0 × 10¹~1.5 × 10² |
| 3 | Ti₃C₂-Sodium | 2 | 2-6.5 | 2.9 × 10³~3.1 × 10³ |
| | Alginate (SA) | | | |
| 4 | Ti₃C₂ | 3 | 1.5-11.2 | 4.5 × 10³~5.0 × 10³ |
| 5 | Ti₃C₂ | 4 | 4.6-4.9 | 4.8 × 10³~5.1 × 10³ |

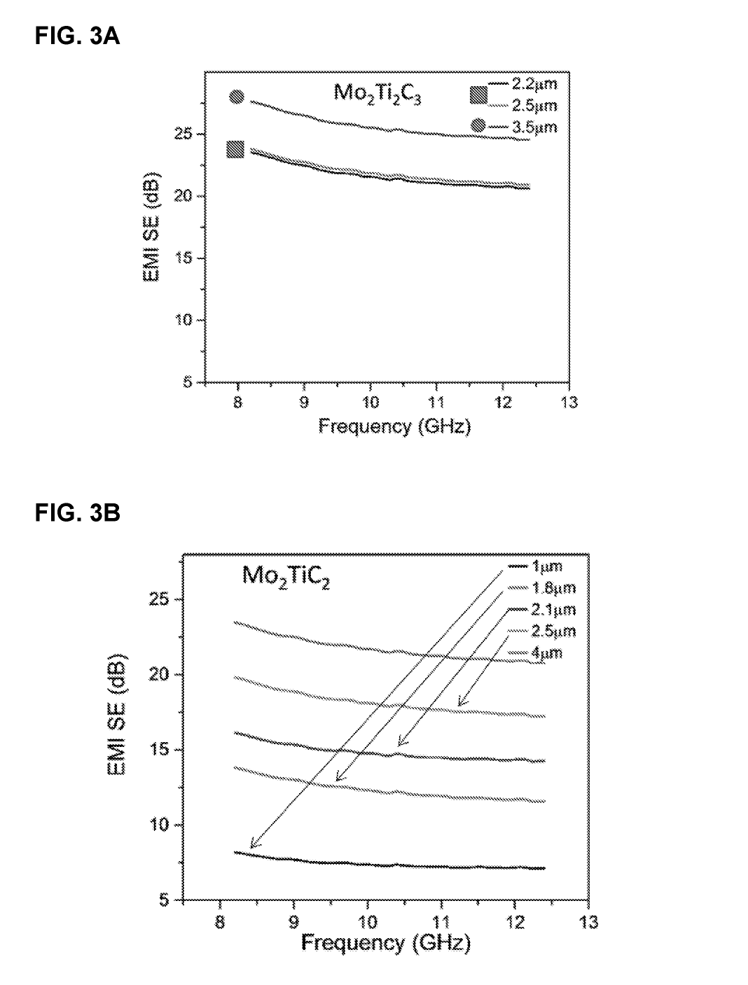

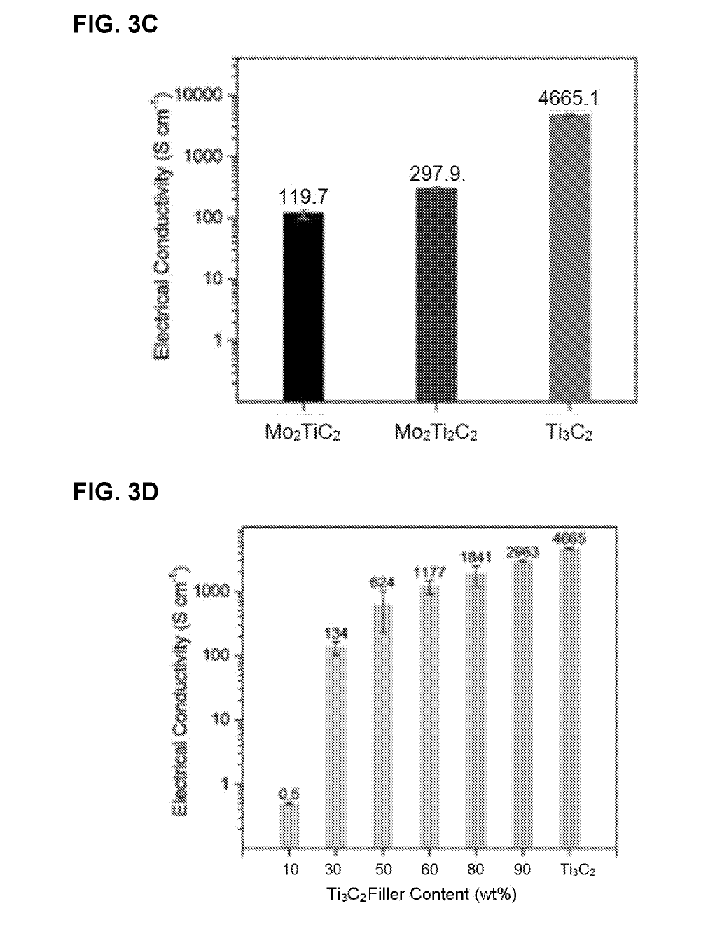

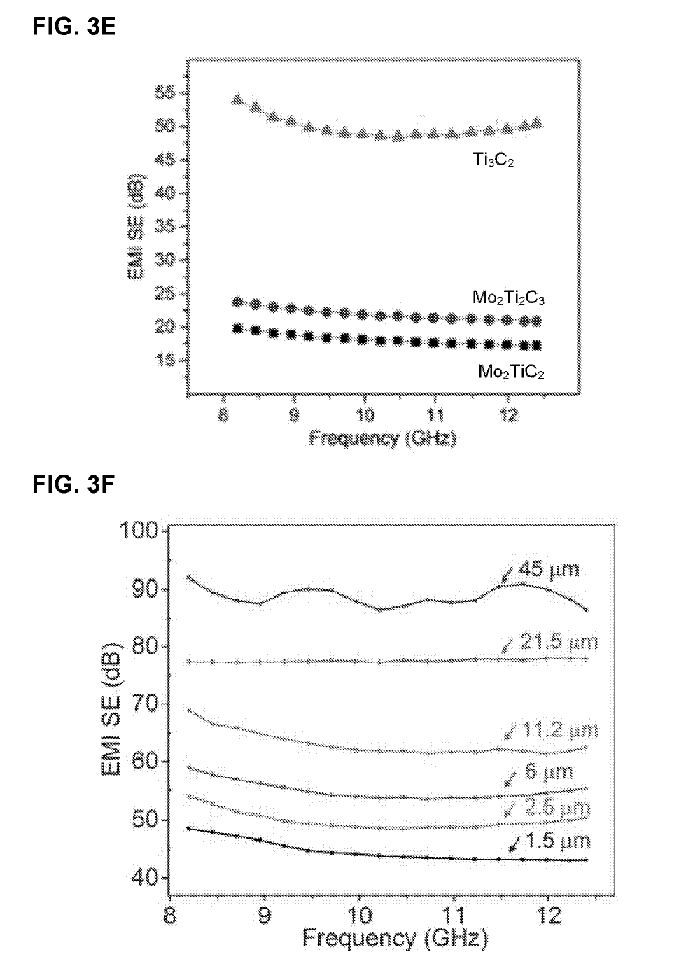

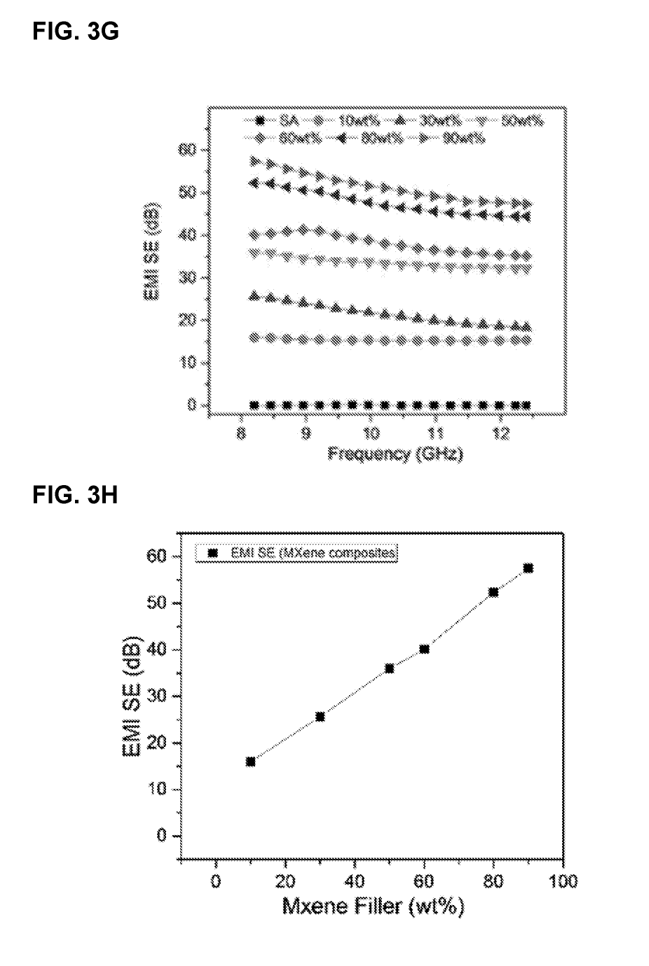

Materials with large electrical conductivity are typically needed to obtain high EMI SE values. FIG. 3C presents the electrical conductivity of three different types of MXenes. A higher electrical conductivity in Mo₂Ti₂C₃Tₓ was observed compared to Mo₂TiC₂Tₓ, which is in agreement with previously reported results. Ti₃C₂Tₓ films showed the highest electrical conductivity among the studied samples, reaching 4600 S cm⁻¹. Such excellent electrical conductivity arises from the high electron density of states near the Fermi level [N(Ef)] as predicted from density functional theory, making this MXene metallic in nature. By contrast, Mo₂Ti₂C₃Tₓ and Mo₂TiC₂Tₓ exhibited lower electrical conductivity values of 119.7 and 297.0 S cm⁻¹, respectively, and semi-conductor-like temperature dependence of conductivity. Electrical conductivities of Ti₃C₂Tₓ-SA polymer composites are plotted in FIG. 3D. With the addition of only 10 wt % Ti₃C₂Tₓ the conductivity of SA polymer rises to 0.5 S cm⁻¹. The large aspect ratio of Ti₃C₂Tₓ flakes likely provides a percolation network at low filler loading, thereby increasing electrical conductivity of the composite sample. As filler content is increased, electrical conductivity increased and reached 3000 S cm⁻¹ for the 90 wt % Ti₃C₂Tₓ-SA composite.

### Example 2.3. Thickness

As thickness is an important factor in determining the electrical conductivity and EMI shielding effectiveness, generally thicknesses were measured using a measurement meter from Heidenhain instruments, which was accurate within ±0.1 μm. Further, to countercheck these measurements, two representative cross sectional scanning electron microscope (SEM) measurements were conducted as shown in FIG. 1B and FIG. 1C. The SEM and thickness meter results were comparable for films of Ti₃C₂ (11.2 μm) and Ti₃C₂-sodium alginate composite (6.5 μm).

### Example 2.4. EMI Shielding

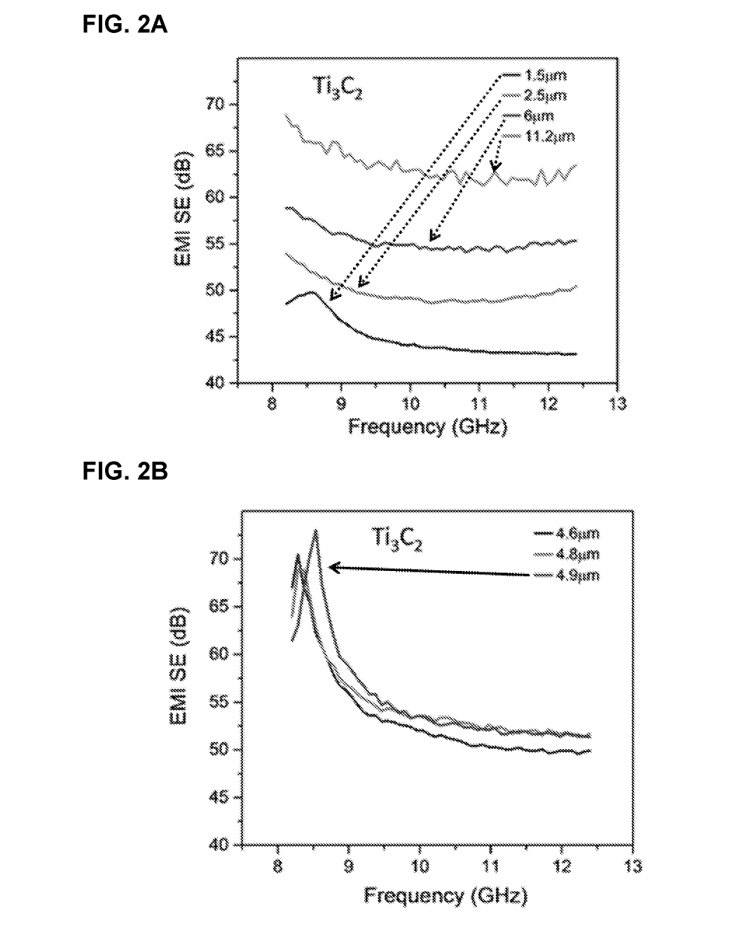

FIGS. 2A and 2B show the EMI shielding effectiveness (EMI SE) of Ti₃C₂ samples as a function of thickness and frequency. In the case of the 11 μm thick Ti₃C₂ film, EMI shielding effectiveness were found to be above 62 dB. This is the highest EMI shielding effectiveness value the present inventors have ever measured for any nanomaterials (at the same sample thickness) including 1D, 2D and 3D materials, which may be ascribed to the high electrical conductivity of Ti₃C₂ film (˜5000 S/cm) and excellent connectivity of large MXene flakes.

Mo₂Ti₂C₃ and Mo₂TiC₂ films EMI shielding effectiveness results are shown in FIGS. 3A and 3B. Some of the Mo-MXene films were very thin and had very small pores in them. In the case of Mo₂Ti₂C₃ films, some micropores were observed which could have been due to the very thin films (1 to 3 μm thickness), which led to formation of some small pores during vacuum filtration process and caused lower integrity/strength. Also, sample packing and handling also caused some small visible holes on the films. In general, Mo₂Ti₂C₃ and Mo₂TiC₂ films showed lower EMI shielding effectiveness compare to Ti₃C₂ films, which can be due to lower electrical conductivity of the Mo-containing two-dimensional transition metal carbides. Another possible reason may be due to the presence of few micropores and holes in the latter that generate electromagnetic leakage. Testing the Mo-MXene films at different powers for multiple times revealed similar results that suggested that the “Mo” based MXenes were not as efficient EMI shielding material as Ti₃C₂. Nevertheless, interestingly enough the EMI shielding effectiveness of less significant Mo₂Ti₂C₃/Mo₂TiC₂ films still show above 20 dB (at 2˜3 μm thick), which is much better than graphene based films as reported previously such as; rGO (20 dB, 15 μm): CARBON 94 (2015) 494-500, and rGO (20 dB, 8.4 μm): Adv. Funct. Mater. 2014, 24, 4542-4548, that still makes “Mo” based MXene a competitor to graphene based shielding materials.

As noted in Table 1, Mo₂TiC₂, being less electrically conductive than Mo₂Ti₂C₃, showed lower EMI shielding effectiveness values. The maximum EMI shielding effectiveness of 4 μm Mo₂TiC₂ film was ˜23 dB, whereas, Mo₂Ti₂C₃ showed EMI shielding effectiveness of ˜27 dB for the 3.5 μm film. The results suggested that Mo₂Ti₂C₃ film, despite being thin, showed better EMI shielding effectiveness than the thicker Mo₂TiC₂ films. This is attributed to the higher electrical conductivity of Mo₂Ti₂C₃ as compared to that of Mo₂TiC₂.

### Example 2.5. Ti₃C₂ Composite

To explore the EMI shielding properties of MXenes, we compared three MXene film compositions with an average thickness of ˜2.5 μm in FIG. 3E. EMI SE is directly proportional to electrical conductivity. Consequently, Ti₃C₂Tₓ, with the best electrical conductivity, gave the highest EMI SE among the studied MXenes. Because thickness plays an important role in EMI SE of any material, EMI SE can be improved simply by increasing the thickness. To investigate this effect, the EMI SE of six Ti₃C₂Tₓ films with different thicknesses was measured. The highest EMI SE value, 92 dB, was recorded for a 45-mm-thick film, enough to block 99.99999994% of incident radiation with only 0.00000006% transmission. Experimental results of a Ti₃C₂Tₓ film in the X-band were comparable to the theoretically calculated values. Experimental measurements on a laminated spray-coated 4-μm thick film confirmed the prediction, showing similar EMI SE values at high and low frequencies. Thus, MXene films maintain excellent EMI SE shielding capability over a broad frequency range.

In general, adequate shielding can be achieved by using thick conventional materials; however, material consumption and weight put such materials at a disadvantage for use in aerospace and telecommunication applications. Therefore, it is important to achieve high EMI SE values with relatively thin films. As discussed elsewhere herein, to further improve MXenes mechanical properties and environmental stability, and to reduce their weight, these carbides can be embedded into polymer matrices. As an example, the Ti₃C₂Tₓ-SA composites were investigated for EMI shielding. Here, the thickness of composite films was fixed between 8 and 9 μm. With increasing MXene content, EMI SE increased, to a maximum of 57 dB for the 90 wt % Ti₃C₂Tₓ-SA sample (FIG. 3G). To obtain a clearer picture, the influence of filler content on EMI SE was plotted at a constant frequency of 8.2 GHz (see FIG. 3H). Shielding mechanism from absorption (SE_{A}) and reflection (SE_{R}) in the Ti₃C₂Tₓ (6 μm) and 60 wt % Ti₃C₂Tₓ-SA (˜8 mm) films were plotted in FIG. 3I at 8.2 GHz. Shielding due to absorption was the dominant mechanism, rather than reflection in pristine MXene and its composites.

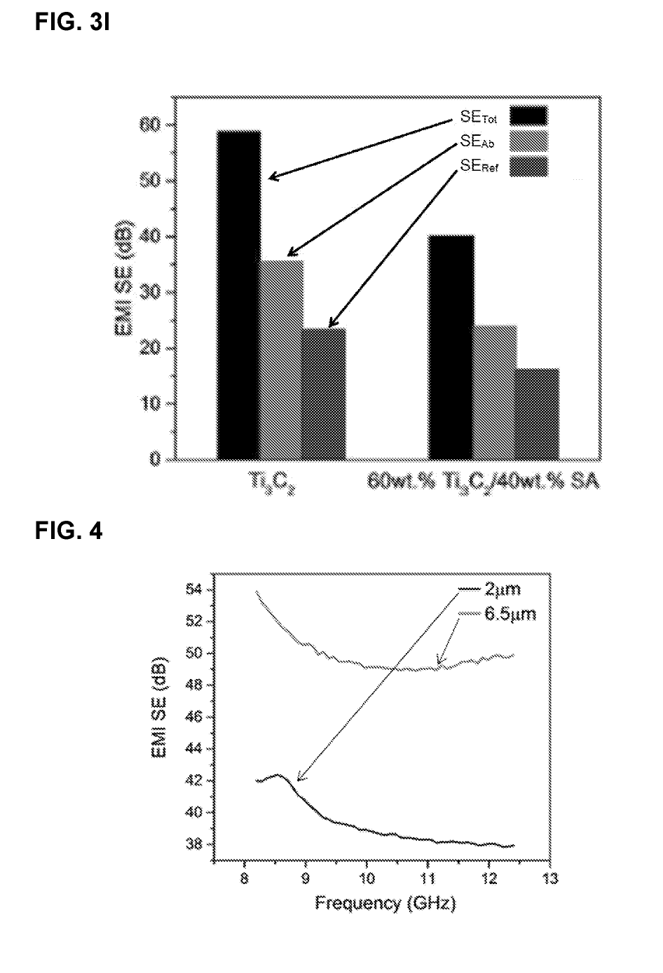

FIG. 4 presents the EMI shielding effectiveness of Ti₃C₂-sodium alginate composite samples (samples #3 in Table 1). Two films were provided with the same mass loading of Ti₃C₂ but with different thickness. A 2 μm film with 90 wt. % of Ti₃C₂ in SA showed EMI shielding effectiveness of nearly 40 dB, while the composite film of almost 6.5 μm thickness with 90 wt. % of Ti₃C₂ showed >50 dB. It is expected that with incorporation of polymer matrix, conductivity declined as did the EMI SE. However, the EMI shielding effectiveness of 40 dB at very small thickness of 2 μm was quite unusual and interesting and was best among the existing polymer composite materials to date. Based on previous experience with graphene/polymer composite systems at almost similar graphene loading (70˜80 wt. %) for <10 μm thick samples never reach above 20 dB. Therefore, it is reasonable to believe that Ti₃C₂-sodium alginate composite performed exceptionally well and was the best known polymer composite available for EMI shielding.

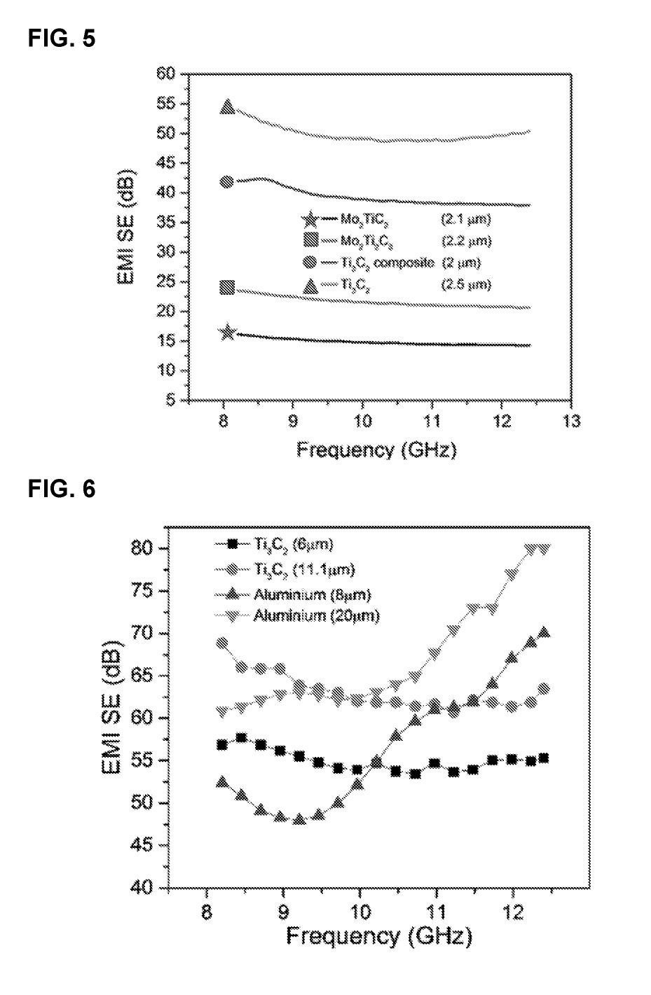

To have a better understanding of all the samples tested here, all of the MXene samples (including composite) were compared at average thickness of ˜2 μm in FIG. 5. Clearly, more conductive samples showed better EMI shielding.

### Example 2.5. Summary

The EMI shielding effectiveness values of all MXenes are appeared to be higher than any other material (except pure metals). As stated earlier, the general commercial shielding requirements demand EMI shielding effectiveness above 30 dB. This requirement was generally met by increasing the shield thickness (above 1 μm) or in case of polymer composites by increasing the filler loading and thickness in parallel. Here, not only higher values of EMI shielding effectiveness were achieved >>30 dB but more significantly at a very small thickness.

### Example 3. Additional Studies

### Example 3.1. Electrical Conductivity of MXene Composites

A total of 11 additional samples (films) were evaluated (One sample 6B was not present). The films were relatively fragile so, it was difficult to determine the electrical conductivity of MXene composites films. The standard process for determining electrical conductivity was to make exact dimension samples, either rectangular or circular, however, as said earlier the films were fragile and easily torn during handling. Moreover, much thickness variation was observed which makes correct determination of electrical conductivity difficult (σ=(Rs×t)⁻¹). Nevertheless, using linear geometry, the results are tabulated Table 2.

TABLE 2
Electrical Conductivity of Ti₃C₂/Polymer composites

| Ti₃C₂ | | | | | |
|---|---|---|---|---|---|
| Content | A Samples | | B Samples | | |
| (wt %) | σ [S cm⁻¹]* | Thickness [μm]^{#} | σ [S cm⁻¹]* | Thickness [μm]^{#} | σ [S cm⁻¹]* |
| 10 | 0.5 | 4.8~6.3 | Not possible | | 0.50 |
| 30 | 113.0 | 10~15 | 155.8 | 5.5~7.5 | 134.4 |
| 50 | 897.6 | 9.9~12.1 | 349.7 | 4.9~6.2 | 623.6 |
| 60 | 1364.7 | 7.5~9 | 980.3 | 4.3~5 | 1172.5 |
| 80 | 1363.3 | 8.2~9.8 | 2317.9 | 3~4.5 | 1840.6 |

| | | | | |
|---|---|---|---|---|
| 90 | 2966.7 | 6.1~7.2 | Not possible | 2966.7 |

*Average electrical conductivity;
^{#}Thickness variation

### Example 3.2. EMI Shielding Effectiveness of MXene Composites

FIGS. 3G, and 3H present the EMI shielding effectiveness of all six samples in given frequency range. Sample designation follows; 10MXene (10 wt % MXene, 90 wt % polymer), 30MXene (30 wt % MXene, 70 wt % polymer) and so on. FIG. 3H shows the effect of filler content on EMI shielding effectiveness at fixed frequency of 8.2 GHz (extracted from FIG. 3G). FIG. 6 presents the comparison of Ti₃C₂ MXene film with that of high purity aluminum foil. Performance on aluminum foil of two different thickness was compared. It was quite surprising that Ti₃C₂ MXene film had almost same EMI shielding effectiveness as pure aluminum film, because the MXene has two order lower electrical conductivity than pure aluminum film.

### Example 3.3. EMI Comparison Table

A more comprehensive table was developed for EMI reference as can be seen in Table 3. The references contain each kind of materials with particular focus on carbon and carbon derivatives. Utmost effort was made to tabulate the references with extracting every important parameter particularly in X-band range (8.2˜12.4 GHz). Few reports of significance, measured in other frequency ranges were also included to make it diversified. Moreover, both the bulk materials and polymer composites were included in each category.

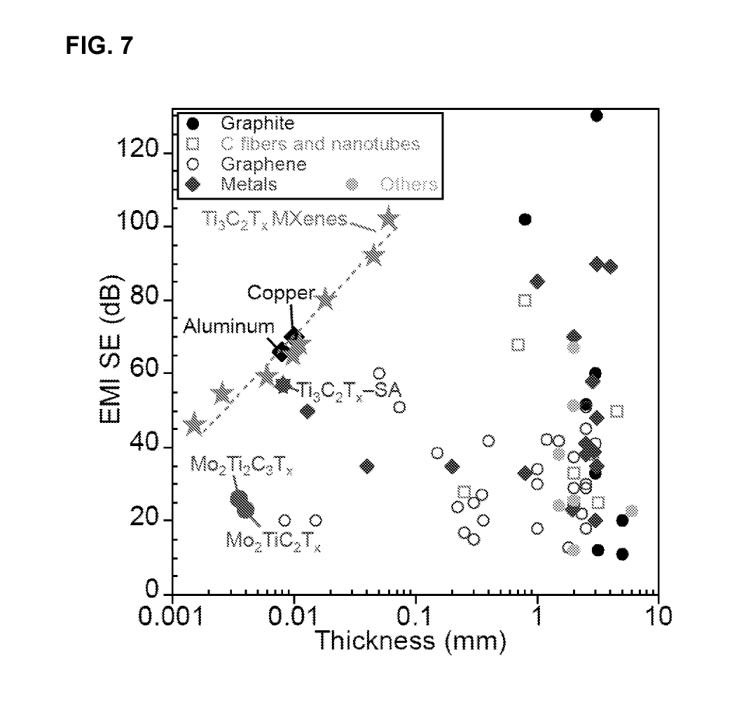

TABLE 3
EMI shielding performance of various shielding materials
in X-band. See following references cited and also FIG. 7

| | | Filler | | Thickness | Conductivity | EMI SE | |
|---|---|---|---|---|---|---|---|
| Type | Filler | [wt %] | Matrix | [mm] | [S m⁻¹] | [dB]* | Ref. |
| Reduced | rGO | 7 | PS | 2.5 | 43.5 | 45.1 | 1 |
| graphene | rGO | 10 | PEI | 2.3 | 0.001 | 22 | 2 |
| oxide | rGO | 0.7 | PDMS | 1 | 180 | 30 | 3 |
| (rGO) | rGO | 20 | wax | 2.0 | <0.1 | 29 | 4 |
| | rGO | 60^{#} | wax | 0.35 | 2500 | 27 | 5 |
| | rGO | 7.5 | WPU | 1 | 16.8 | 34 | 6 |
| | rGO | 15 | epoxy | / | 10 | 21 | 7 |
| | rGO | 30 | PS | 2.5 | 1.25 | 29 | 8 |
| | SrGO | 15 | PS | 2 | 33 | 24.5^{§} | 9 |
| | rGO | 10 | PU | 60 | 0.06 | 39.4 | 10 |
| | rGO | 4 | PI | 0.073 | 2 × 10⁵ | 51 | 11 |
| | B,N-doped rGO | Bulk | / | 1.2 | 124 | 42^{Δ} | 12 |
| | S-doped rGO | Bulk | / | 0.15 | 3.1 × 10⁴ | 38.5^{§} | 13 |
| | Graphene film | Bulk | / | 0.25 | / | 17^{Δ} | 14 |
| | Graphene film | Bulk | / | 0.050 | 1.13 × 10⁴ | 60 | 15 |
| | Graphene film | Bulk | / | 0.0084 | 10⁵ | 20 | 16 |
| | Graphene film | Bulk | / | 0.015 | 2.4 × 10⁴ | 20.2^{§} | 17 |
| | Graphene foam | Bulk | / | 0.3 | 310 | 25 | 18 |
| rGO | rGO/δ-Fe₂O₃ | 40 | PVA | 0.36 | 3 | 20.3 | 19 |
| with | rGO/γ- Fe₂O₃ | 75 | PANI | 2.5 | 80 | 51 | 20 |
| magnetic | rGO/Fe₃O₄ | 35 | PVA | 0.3 | <0.1 | 15 | 21 |
| fillers | rGO/Fe₃O₄ | 66 | PANI | 2.5 | 260 | 30^{Δ} | 22 |
| | rGO/CF/γ-Fe₂O₃ | 50 | Phenolic | 0.4 | 1.7 × 10⁴ | 41.8 | 23 |
| | | | resin | | | | |
| | rGO/Fe₃O₄ | 10 | PVC | 1.8 | 7.7 × 10 ⁻⁴ | 13 | 24 |
| | rGO/Fe₃O₄ | 10 | PEI | 2.5 | 10⁻⁴ | 18 | 25 |
| | rGO/Fe₃O₄ | Bulk | / | 0.20-0.25 | 5000 | 24 | 26 |
| | rGO/Fe₃O₄ | Bulk | / | 3 | 700 | 41 | 27 |
| | rGO-BaTiO₃ | Bulk | / | 1.5 | / | 41.7 | 28 |
| | rGO-Ba Ferrite | Bulk | / | 1 | 98 | 18 | 29 |
| | rGO/CNT/Fe₃O₄ | Bulk | / | 2 | / | 37.5 | 30 |
| Graphite/ | CB | 15 | SEBS | 5 | 22 | 20 | 31 |
| CB | Graphite | 25^{#} | PA 6,6 | 3.2 | / | 12^{§} | 32 |
| | Graphite | 7.05^{#} | PE | 2.5 | 10 | 51.6 | 33 |
| | Graphite | 18.7^{#} | PE | 3 | — | 33 | 34 |
| | Graphite | 2 | Epoxy | 5 | 2.6 | 11 | 35 |
| | Graphite | 15 | ABS | 3 | 16 | 60 | 36 |
| Carbon | MWCNT | 76 | WPU | 0.8 | 2.1 × 10³ | 80 | 37 |
| nanotubes | CNT | 0.66 | Epoxy | 2 | 516 | 33 | 38 |
| | MWCNT | 76.2 | WPU | 4.5 | 44.6 | 50 | 39 |
| | SWCNT | 15 | Epoxy | 2 | 20 | 25 | 40 |
| | CNT | 7 | PS | / | / | 18.5 | 41 |
| | CNT | 25 | Coal tar | 0.6 | 1.1 × 10³ | −56 | 42 |
| Carbon | CF/Fe₃O₄ | 10 | Epoxy | 13 | 0.2 | 20 | 43 |
| Fiber | CF | 40_{#} | PES | 2.87 | / | 38 | 44 |
| | CF | 10_{#} | PP | 3.2 | 10 | 25 | 45 |
| | CF | 15 | PS | / | 0.1 | 19 | 46 |
| | CF-GN | 17.2 | wax | 0.22-0.27 | 800 | 28 | 47 |
| | CF/7.7 × 10⁻⁴ | 5 | PDMS | 0.7 | / | 67.9 | 48 |
| Metals | Ni | 10^{#} | PP | 3 | 100 | 20 | 49 |
| | Ni/CB | 50 | Phenolic | 1 | 31.6 | 85 | 50 |
| | | | resin | | | | |
| | Ni | 40^{#} | PVDF | 1.95 | <0.1 | 23 | 51 |
| | Ag/CF | 4.5 | Epoxy | 2.5 | / | 38 | 52 |
| | Ag Nanowires | 75 phr | Epoxy | 0.040 | 4.7 × 10³ | 35 | 53 |
| | Ag Nanowires | 14^{#} | PANI | 0.013 | 5.3 × 10⁵ | 50 | 54 |
| | Cu/Graphite | 20 | PVC | 2 | 80 | 70 | 55 |
| | Ni Fiber | 7# | PES | 2.85 | / | 58 | 56 |
| | Al Flakes | 20^{#} | PES | 2.9 | / | 39 | 44 |
| | Copper | Bulk | / | 3.1 | / | 90 | 56 |
| | Stainless steel | 10^{#} | PES | 3.08 | / | 35 | 44 |
| | Stainless steel | Bulk | / | 4 | / | 89 | 56 |
| | Stainless steel | 1.1^{#} | PP | 3.1 | 0.1 | 48 | 57 |
| | Cu Nanowires | 2.1^{#} | PS | 0.2 | / | 35 | 58 |
| | Ag Nanowires | 2.5^{#} | PS | 0.8 | 1.9 × 10³ | 33 | 59 |
| | Ni—Co Fiber | 30 | wax | 2.5 | 1.3 × 10³ | 41.2 | 60 |
| Others | Caron Foam | Bulk | / | 2 | 2.4 × 10² | 51.2 | 61 |
| | MoS₂ | 30 | Glass | 1.5 | 100 | 24.2 | 62 |
| | MoS₂ | 60 | wax | 2.4 | 2.2 × 10⁻⁵ | 38.4 (RL) | 63 |
| | rGO-SiO₂ | Bulk | / | 1.5 | 33 | 38 | 64 |
| | Ni Ferrite | / | PVDF | 2 | / | 67 | 65 |
| | Fe₂O₃/ash | 60 | PP | 2 | 1 | 25.5^{Δ} | 66 |
| | Ba Ferrite | 38.2 | PPY | 2 | >1 | 12 | 67 |
| | Fe₂O₃ | / | PEDOT | 6 | 40 | 22.8 | 68 |
| | Ba Ferrite* | / | PEDOT | / | / | 22.5^{Δ} | 69 |
| | Carbon Aerogel | Bulk | / | 10 | 133.3 | 51 | 70 |
| | Zn Ferrite | 50 | PPY | 2.7 | / | −28.9 | 71 |
| | | | | | | (RL) | |
| | Mn Ferrite | 15 | PPY | 1.5 | / | −12 | 72 |
| | | | | | | (RL) | |
| | Fe₃O₄ | 40 | PANI | 2 | / | −33 | 73 |
| | | | | | | (RL) | |
| | Carbonyl Iron | 50 | PPY | 2.2 | / | −39.5 | 74 |
| | | | | | | (RL) | |
| Commercial | Commercial | / | / | 2 | 126.5 | 40^{§} | 75* |
| products | Carbon Foam | | | | | | |
| | Al Foil | Bulk | / | 0.002 | 2.8 × 10⁷ | 70 | This work |
| | Al Foil | Bulk | / | 0.008 | 2.8 × 10⁷ | 80 | |
| MXenes | Mo₂TiC₂ | Bulk | / | 0.004 | 1 × 10⁴ | 23 | |
| | Mo₂Ti₂C₃ | Bulk | / | 0.0035 | 2.5 × 10⁴ | 26 | |
| | Ti₃C₂ | Bulk | / | 0.011 | 4.8 × 10⁵ | 65 | |
| | Ti₃C₂ | 60 | SA | 0.006 | 1.2 × 10³ | 40 | |

*Values in bracket indicate maximum EMI shielding effectiveness value in measure range.
EMI shielding effectiveness was obtained mainly in X-band (8.2-12.4 GHz) except otherwise specified;
/: values not provided;
^{#}Vol %;
RL; Reflection loss;
^{Δ}Ku-band (12.4-18 GHz);
^{§}L-band; 1-2 GHz, S-band; 2-4 GHz.

### REFERENCES

1. D. X. Yan, H. Pang, B. Li, R. Vajtai, L. Xu, P. G. Ren, J. H. Wang and Z. M. Li, Advanced Functional Materials, 2015, 25, 559-566.
2. J. Ling, W. Zhai, W. Feng, B. Shen, J. Zhang and W. g. Zheng, ACS Applied Materials & Interfaces, 2013, 5, 2677-2684.
3. Z. Chen, C. Xu, C. Ma, W. Ren and H.-M. Cheng, Advanced Materials, 2013, 25, 1296-1300.
4. B. Wen, X. X. Wang, W. Q. Cao, H. L. Shi, M. M. Lu, G. Wang, H. B. Jin, W. Z. Wang, J. Yuan and M. S. Cao, Nanoscale, 2014, 6, 5754-5761.
5. W.-L. Song, M.-S. Cao, M.-M. Lu, S. Bi, C.-Y. Wang, J. Liu, J. Yuan and L.-Z. Fan, Carbon, 2014, 66, 67-76.
6. S.-T. Hsiao, C.-C. M. Ma, W.-H. Liao, Y.-S. Wang, S.-M. Li, Y.-C. Huang, R.-B. Yang and W.-F. Liang, ACS Applied Materials & Interfaces, 2014, 6, 10667-10678.
7. J. Liang, Y. Wang, Y. Huang, Y. Ma, Z. Liu, J. Cai, C. Zhang, H. Gao and Y. Chen, Carbon, 2009, 47, 922-925.
8. D.-X. Yan, P.-G. Ren, H. Pang, Q. Fu, M.-B. Yang and Z.-M. Li, Journal of Materials Chemistry, 2012, 22, 18772-18774.
9. F. Shahzad, S. Yu, P. Kumar, J.-W. Lee, Y.-H. Kim, S. M. Hong and C. M. Koo, Composite Structures, 2015, 133, 1267-1275.
10. B. Shen, Y. Li, W. Zhai and W. Zheng, ACS applied materials & interfaces, 2016.
11. Y. Li, B. Shen, X. Pei, Y. Zhang, D. Yi, W. Zhai, L. Zhang, X. Wei and W. Zheng, Carbon, 2016, 100, 375-385.
12. S. Umrao, T. K. Gupta, S. Kumar, V. K. Singh, M. K. Sultania, J. H. Jung, I.-K. Oh and A. Srivastava, ACS Applied Materials & Interfaces, 2015, 7, 19831-19842.
13. F. Shahzad, P. Kumar, Y.-H. Kim, S. M. Hong and C. M. Koo, ACS Applied Materials & Interfaces, 2016, DOI: 10.1021/acsami.6b00418.
14. P. Tripathi, C. R. Prakash Patel, A. Dixit, A. P. Singh, P. Kumar, M. A. Shaz, R. Srivastava, G. Gupta, S. K. Dhawan, B. K. Gupta and O. N. Srivastava, RSC Advances, 2015, 5, 19074-19081.
15. L. Zhang, N. T. Alvarez, M. Zhang, M. Haase, R. Malik, D. Mast and V. Shanov, Carbon, 2015, 82, 353-359.
16. B. Shen, W. Zhai and W. Zheng, Advanced Functional Materials, 2014, 24, 4542-4548.
17. P. Kumar, F. Shahzad, S. Yu, S. M. Hong, Y.-H. Kim and C. M. Koo, Carbon, 2015, 94, 494-500.
18. B. Shen, Y. Li, D. Yi, W. Zhai, X. Wei and W. Zheng, Carbon, 2016, 102, 154-160.
19. B. Yuan, C. Bao, X. Qian, L. Song, Q. Tai, K. M. Liew and Y. Hu, Carbon, 2014, 75, 178-189.
20. A. P. Singh, M. Mishra, P. Sambyal, B. K. Gupta, B. P. Singh, A. Chandra and S. K. Dhawan, Journal of Materials Chemistry A, 2014, 2, 3581-3593.
21. B. B. Rao, P. Yadav, R. Aepuru, H. Panda, S. Ogale and S. Kale, Physical Chemistry Chemical Physics, 2015, 17, 18353-18363.
22. K. Singh, A. Ohlan, V. H. Pham, R. Balasubramaniyan, S. Varshney, J. Jang, S. H. Hur, W. M. Choi, M. Kumar and S. Dhawan, Nanoscale, 2013, 5, 2411-2420.
23. A. P. Singh, P. Garg, F. Alam, K. Singh, R. B. Mathur, R. P. Tandon, A. Chandra and S. K. Dhawan, Carbon, 2012, 50, 3868-3875.
24. K. Yao, J. Gong, N. Tian, Y. Lin, X. Wen, Z. Jiang, H. Na and T. Tang, RSC Advances, 2015, 5, 31910-31919.
25. B. Shen, W. Zhai, M. Tao, J. Ling and W. Zheng, ACS Applied Materials & Interfaces, 2013, 5, 11383-11391.
26. W.-L. Song, X.-T. Guan, L.-Z. Fan, W.-Q. Cao, C.-Y. Wang, Q.-L. Zhao and M.-S. Cao, Journal of Materials Chemistry A, 2015, 3, 2097-2107.
27. M. Mishra, A. P. Singh, B. P. Singh, V. N. Singh and S. K. Dhawan, Journal of Materials Chemistry A, 2014, 2, 13159-13168.
28. Q. Yuchang, W. Qinlong, L. Fa, Z. Wancheng and Z. Dongmei, Journal of Materials Chemistry C, 2016, 4, 371-375.
29. M. Verma, A. P. Singh, P. Sambyal, B. P. Singh, S. K. Dhawan and V. Choudhary, Physical Chemistry Chemical Physics, 2015, 17, 1610-1618.
30. A. P. Singh, M. Mishra, D. P. Hashim, T. N. Narayanan, M. G. Hahm, P. Kumar, J. Dwivedi, G. Kedawat, A. Gupta, B. P. Singh, A. Chandra, R. Vajtai, S. K. Dhawan, P. M. Ajayan and B. K. Gupta, Carbon, 2015, 85, 79-88.
31. S. Kuester, C. Merlini, G. M. O. Barra, J. C. Ferreira Jr, A. Lucas, A. C. de Souza and B. G. Soares, Composites Part B: Engineering, 2016, 84, 236-247.
32. Q. J. Krueger and J. A. King, Advances in Polymer Technology, 2003, 22, 96-111.
33. X. Jiang, D.-X. Yan, Y. Bao, H. Pang, X. Ji and Z.-M. Li, RSC Advances, 2015, 5, 22587-22592.
34. V. Panwar and R. M. Mehra, Polymer Engineering & Science, 2008, 48, 2178-2187.
35. G. De Bellis, A. Tamburrano, A. Dinescu, M. L. Santarelli and M. S. Saito, Carbon, 2011, 49, 4291-4300.
36. V. K. Sachdev, K. Patel, S. Bhattacharya and R. P. Tandon, Journal of Applied Polymer Science, 2011, 120, 1100-1105.
37. Z. Zeng, M. Chen, H. Jin, W. Li, X. Xue, L. Zhou, Y. Pei, H. Zhang and Z. Zhang, Carbon, 2016, 96, 768-777.
38. Y. Chen, H. B. Zhang, Y. Yang, M. Wang, A. Cao and Z. Z. Yu, Advanced Functional Materials, 2016, 26, 447-455.
39. Z. Zeng, H. Jin, M. Chen, W. Li, L. Zhou and Z. Zhang, Advanced Functional Materials, 2016, 26, 303-310.
40. Y. Huang, N. Li, Y. Ma, F. Du, F. Li, X. He, X. Lin, H. Gao and Y. Chen, Carbon, 2007, 45, 1614-1621.
41. Y. Yang, M. C. Gupta, K. L. Dudley and R. W. Lawrence, Nano Letters, 2005, 5, 2131-2134.
42. A. Chaudhary, S. Kumari, R. Kumar, S. Teotia, B. P. Singh, A. P. Singh, S. K. Dhawan and S. R. Dhakate, ACS Applied Materials & Interfaces, 2016, DOI: 10.1021/acsami.5b12334.
43. M. Crespo, N. Méndez, M. González, J. Baselga and J. Pozuelo, Carbon, 2014, 74, 63-72.
44. L. Li and D. D. L. Chung, Composites, 1994, 25, 215-224.
45. A. Ameli, P. U. Jung and C. B. Park, Carbon, 2013, 60, 379-391.
46. Y. Yang, M. C. Gupta, K. L. Dudley and R. W. Lawrence, Advanced Materials, 2005, 17, 1999-2003.
47. W.-L. Song, J. Wang, L.-Z. Fan, Y. Li, C.-Y. Wang and M.-S. Cao, ACS Applied Materials & Interfaces, 2014, 6, 10516-10523.
48. M. Bayat, H. Yang, F. K. Ko, D. Michelson and A. Mei, Polymer, 2014, 55, 936-943.
49. K. Wenderoth, J. Petermann, K. D. Kruse, J. L. ter Haseborg and W. Krieger, Polymer composites, 1989, 10, 52-56.
50. F. El-Tantawy, N. A. Aal and Y. K. Sung, Macromolecular Research, 2005, 13, 194-205.
51. H. Gargama, A. K. Thakur and S. K. Chaturvedi, Journal of Applied Physics, 2015, 117, 224903.
52. J. Li, S. Qi, M. Zhang and Z. Wang, Journal of Applied Polymer Science, 2015, 132, n/a-n/a.
53. N. M. Abbasi, H. Yu, L. Wang, A. Zain ul, W. A. Amer, M. Akram, H. Khalid, Y. Chen, M. Saleem, R. Sun and J. Shan, Materials Chemistry and Physics, 2015, 166, 1-15.
54. F. Fang, Y.-Q. Li, H.-M. Xiao, N. Hu and S.-Y. Fu, Journal of Materials Chemistry C, 2016, DOI: 10.1039/C5TC04406E.
55. A. A. Al-Ghamdi and F. El-Tantawy, Composites Part A: Applied Science and Manufacturing, 2010, 41, 1693-1701.
56. X. Shui and D. D. L. Chung, Journal of Electronic Materials, 26, 928-934.
57. A. Ameli, M. Nofar, S. Wang and C. B. Park, ACS Applied Materials & Interfaces, 2014, 6, 11091-11100.
58. M. H. Al-Saleh, G. A. Gelves and U. Sundararaj, Composites Part A: Applied Science and Manufacturing, 2011, 42, 92-97.
59. M. Arjmand, A. A. Moud, Y. Li and U. Sundararaj, RSC Advances, 2015, 5, 56590-56598.
60. X. Huang, B. Dai, Y. Ren, J. Xu and P. Zhu, J. Nanomaterials, 2015, 2015, 2-2.
61. L. Zhang, M. Liu, S. Roy, E. K. Chua, K. Y. See and X. Hu, ACS applied materials & interfaces, 2016.
62. Q. Wen, W. Zhou, J. Su, Y. Qing, F. Luo and D. Zhu, Journal of Alloys and Compounds, 2016, 666, 359-365.
63. M.-Q. Ning, M.-M. Lu, J.-B. Li, Z. Chen, Y.-K. Dou, C.-Z. Wang, F. Rehman, M.-S. Cao and H.-B. Jin, Nanoscale, 2015, 7, 15734-15740.
64. B. Wen, M. Cao, M. Lu, W. Cao, H. Shi, J. Liu, X. Wang, H. Jin, X. Fang and W. Wang, Advanced Materials, 2014, 26, 3484-3489.
65. B.-W. Li, Y. Shen, Z.-X. Yue and C.-W. Nan, Applied Physics Letters, 2006, 89, 132504.
66. S. Varshney, A. Ohlan, V. K. Jain, V. P. Dutta and S. K. Dhawan, Industrial & Engineering Chemistry Research, 2014, 53, 14282-14290.
67. P. Xu, X. Han, C. Wang, H. Zhao, J. Wang, X. Wang and B. Zhang, The Journal of Physical Chemistry B, 2008, 112, 2775-2781.
68. K. Singh, A. Ohlan, P. Saini and S. K. Dhawan, Polymers for Advanced Technologies, 2008, 19, 229-236.
69. A. Ohlan, K. Singh, A. Chandra and S. K. Dhawan, ACS Applied Materials & Interfaces, 2010, 2, 927-933.
70. Y.-Q. Li, Y. A. Samad, K. Polychronopoulou and K. Liao, ACS Sustainable Chemistry & Engineering, 2015, 3, 1419-1427.
71. Y. Li, R. Yi, A. Yan, L. Deng, K. Zhou and X. Liu, Solid State Sciences, 2009, 11, 1319-1324.
72. S. H. Hosseini and A. Asadnia, J. Nanomaterials, 2012, 2012, 3-3.
73. H. Xiao and W. Yuan-Sheng, Physica Scripta, 2007, 2007, 335.
74. M. Sui, X. Lü, A. Xie, W. Xu, X. Rong and G. Wu, Synthetic Metals, DOI: http://dx.doi.org/10.1016/j.synthmet.2015.09.025.
75. F. Moglie, D. Micheli, S. Laurenzi, M. Marchetti and V. Mariani Primiani, Carbon, 2012, 50, 1972-1980.

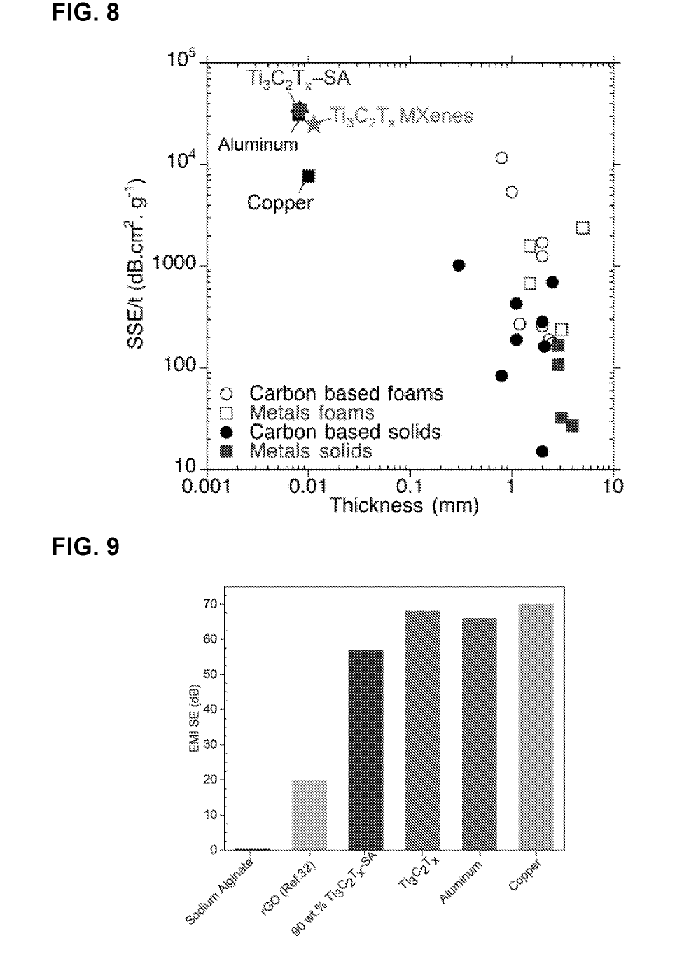

Recently, the concept of foam structures has gained tremendous interest as a way to reduce the density of shielding materials. Lightweight materials are a necessity for aerospace applications; therefore, some metals (such as copper and silver) that possess high EMI SE values are less useful. When considering a material's density, specific EMI shielding effectiveness (SSE) is used as a criterion to evaluate different materials. However, SSE alone is not a sufficient parameter for understanding overall effectiveness, as a higher SSE can simply be achieved at a larger thickness, which directly increases the weight of the final product. Therefore, a more realistic parameter is to divide SSE by the material thickness (SSE/t). Such a parameter is highly valuable for determining the effectiveness of a material by incorporating three important factors: EMI SE, density, and thickness. Interestingly, SSE/t values for MXene and MXene-SA composites are much higher than those for other materials of different categories. As a representative example, a 90 wt % Ti₃C₂Tₓ-SA composite sample gives a SSE/t of 30,830 dB cm² g⁻¹, which is several times higher than those of the other materials studied thus far (FIG. 8). This finding is notable because several commercial requirements for an EMI shielding product are engrained in a single material, such as high EMI SE (57 dB), low density (2.31 g cm⁻³), small thickness (8 μm, reducing net weight and volume), oxidation resistance (due to polymer binder), high flexibility (a feature of 2D films), and simple processing (mixing and filtration or spray-coating). Going a step further, Ti₃C₂Tₓ and Ti₃C₂Tₓ-SA composites were compared with pure aluminum (8 μm) and copper (10 μm) foils (FIG. 9). Ti₃C₂Tₓ, which has two orders of magnitude lower electrical conductivity than these metals, shows EMI SE values similar to those of metals. For comparison, thermally reduced graphene oxide film (8.4 μm) that possessed lower electrical conductivity is also plotted and fell far below the other materials.

### Example 3.4—A Possible Mechanism

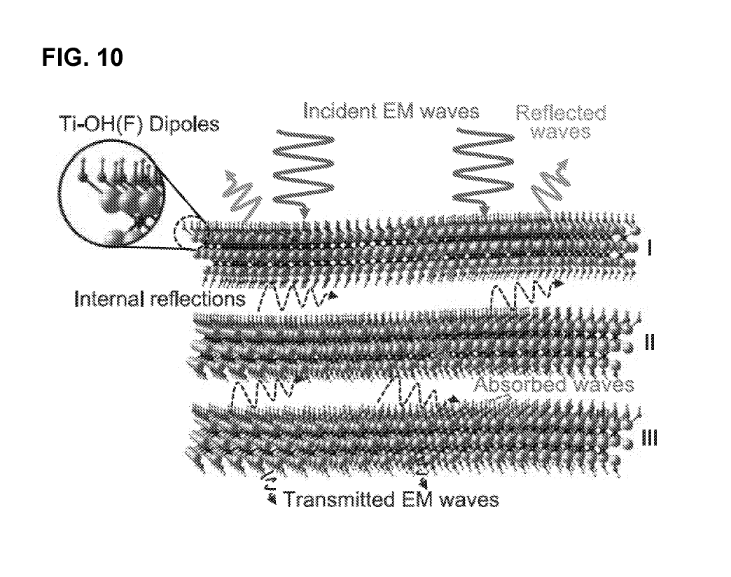

The massive EMI SE of these two-dimensional crystalline transition metal carbides may be understood from several proposed mechanisms shown in FIG. 10, as illustrated for MXene materials While presented as possible mechanisms, the inventive methods are not constrained by the correctness of this, or any other, proposed mechanism. The EMI shielding originates from the excellent electrical conductivity of two-dimensional crystalline transition metal carbides and partially from the layered architecture of the films. In this representation, incoming EM waves (green arrows) strike the surface of a two-dimensional transition-metal carbide coating. Because reflection occurs before absorption, part of the EM waves is immediately reflected from the surface owing to a large number of charge carriers from the highly conducting surface (light blue arrows), whereas induced local dipoles, resulting from termination groups, help with absorption of the incident waves passing through the two-dimensional transition-metal carbide structure (dashed blue arrows). Transmitted waves with less energy are then subjected to the same process when they encounter the next two-dimensional transition-metal carbide, giving rise to multiple internal reflections (dashed black arrows), as well as more absorption. Each time an EM wave is transmitted through a two-dimensional transition-metal carbide coating, its intensity is substantially decreased, resulting in an overall attenuated or completely eliminated EM wave.

More specifically, as EMWs strike the surface of a carbide flake, some EM waves are immediately reflected because of abundant free electrons at the highly conductive surface. The remaining waves pass through the lattice structure where interaction with the high electron density of MXene induces currents that contribute to ohmic losses, resulting in a drop in energy of the EMWs. The surviving EMWs, after passing through the first layer of Ti₃C₂Tₓ (marked as “I” in FIG. 10), encounter the next barrier layer (marked as “II”), and the phenomenon of EMW attenuation repeats. Simultaneously, layer II acts as a reflecting surface and gives rise to multiple internal reflections. The EMWs can be reflected back and forth between the layers (I, II, III, and so on) until completely absorbed in the structure. This is in marked contrast to pure metals that have a regular crystallographic structure and no interlayer reflecting surface available to provide the internal multiple reflection phenomenon. Thus, the nacre-like (or laminated) structure provides two-dimensional carbides with the ability to behave as a multi-level shield. Considering a 45-μm-thick Ti₃C₂Tₓ film, thousands of 2D Ti₃C₂Tₓ sheets act as barriers to EMWs. As the overall EMI value goes above 15 dB, it is generally assumed that the contribution from internal reflections is minimal. However, in the layered structure of MXenes and the other two-dimensional carbides, multiple internal reflections cannot be ignored. The multiple reflection effect, nevertheless, is included with absorption because the re-reflected waves get absorbed or dissipated in the form of heat within the material. Furthermore, the surface terminations may play a role aswell. Local dipoles between Ti and terminating groups (—F, ═O, or —OH) may be created when subjected to an alternating electromagnetic field. Fluorine, in particular, being highly electronegative, can induce this kind of dipole polarization. The ability of each element to interact with incoming EMWs leads to polarization losses, which in turn improve the overall shielding.

As those skilled in the art will appreciate, numerous modifications and variations of the present invention are possible in light of these teachings, and all such are contemplated hereby. All references cited within this specification are incorporated by reference in their entireties for all purposes, or at least for their teachings in the context of their recitation.

What is claimed:

1. A method for shielding an object from electromagnetic interference comprising superposing at least one surface of the object with either a contacting or non-contacting coating comprising a two-dimensional transitional metal carbide composition having electrically conductive surfaces.

2. The method of claim 1, wherein the two-dimensional transition metal carbide comprises a composition comprising at least one layer having first and second surfaces, each layer comprising:
a substantially two-dimensional array of crystal cells,
each crystal cell having an empirical formula of Mₙ₊₁Xₙ, such that each X is positioned within an octahedral array of M,
wherein M is at least one Group IIIB, IVB, VB, or VIB metal,
wherein each X is C, N, or a combination thereof;
n=1, 2, or 3.

3. The method of claim 2, wherein the two-dimensional transition metal carbide comprises a plurality of stacked layers

4. The method of claim 2, wherein at least one of said surfaces of each layer has surface terminations comprising alkoxide, carboxylate, halide, hydroxide, hydride, oxide, sub-oxide, nitride, sub-nitride, sulfide, thiol, or a combination thereof

5. The method of claim 2, wherein at least one of said surfaces of each layer has surface terminations comprising alkoxide, fluoride, hydroxide, oxide, sub-oxide, or a combination thereof

6. The method of claim 2, wherein both surfaces of each layer have said surface terminations comprising alkoxide, fluoride, hydroxide, oxide, sub-oxide, or a combination thereof.

7. The method of claim 2, wherein M is at least one Group IVB, Group VB, or Group VIB metal, preferably Ti, Nb, V, or Ta

8. The method of claim 2, wherein M is Ti, and n is 1 or 2.

9. The method of claim 1, wherein the two-dimensional transition metal carbide comprises a composition comprising at least one layer having first and second surfaces, each layer comprising:
a substantially two-dimensional array of crystal cells,
each crystal cell having an empirical formula of M′₂M″ₙXₙ₊₁, such that each X is positioned within an octahedral array of M′ and M″, and where M″ₙ are present as individual two-dimensional array of atoms intercalated (sandwiched) between a pair of two-dimensional arrays of M′ atoms,
wherein M′ and M″ are different Group IIIB, IVB, VB, or VIB metals (especially where M′ and M″ are Ti, V, Nb, Ta, Cr, Mo, or a combination thereof),
wherein each X is C, N, or a combination thereof; and
n=1 or 2.

10. The method of claim 9, wherein n is 1, M′ is Mo, and M″ is Nb, Ta, Ti, or V, or a combination thereof.

11. The method of claim 9, wherein n is 2, M′ is Mo, Ti, V, or a combination thereof, and M″ is Cr, Nb, Ta, Ti, or V, or a combination thereof.

12. The method of claim 9, wherein M′₂M″ₙXₙ₊₁ comprises Mo₂TiC₂, Mo₂VC₂, Mo₂TaC₂, Mo₂NbC₂, Mo₂Ti₂C₃, Cr₂TiC₂, Cr₂VC₂, Cr₂TaC₂, Cr₂NbC₂, Ti₂NbC₂, Ti₂TaC₂, V₂TaC₂, or V₂TiC₂, or a nitride or carbonitride analog thereof

13. The method of claim 9, wherein M′₂M″ₙXₙ₊₁, comprises Mo₂TiC₂, Mo₂VC₂, Mo₂TaC₂, or Mo₂NbC₂, or a nitride or carbonitride analog thereof.

14. The method of claim 9, wherein M′₂M″ₙXₙ₊₁ comprises Mo₂Ti₂C₃, Mo₂V₂C₃, Mo₂Nb₂C₃, Mo₂Ta₂C₃, Cr₂Ti₂C₃, Cr₂V₂C₃, Cr₂Nb₂C₃, Cr₂Ta₂C₃, Nb₂Ta₂C₃, Ti₂Nb₂C₃, Ti₂Ta₂C₃, V₂Ta₂C₃, V₂Nb₂C₃, or V₂Ti₂C₃, or a nitride or carbonitride analog thereof.

15. The method of claim 9, wherein M′₂M″ₙXₙ₊₁ comprises Mo₂Ti₂C₃, Mo₂V₂C₃, Mo₂Nb₂C₃, Mo₂Ta₂C₃, Ti₂Nb₂C₃, Ti₂Ta₂C₃, or V₂Ta₂C₃, or a nitride or carbonitride analog thereof.

16. The method of claim 9, wherein the two-dimensional transition metal carbide comprises a plurality of stacked layers

17. The method of claim 9, wherein at least one of said surfaces of each layer has surface terminations comprising alkoxide, carboxylate, halide, hydroxide, hydride, oxide, sub-oxide, nitride, sub-nitride, sulfide, thiol, or a combination thereof

18. The method of claim 9, wherein at least one of said surfaces of each layer has surface terminations comprising alkoxide, fluoride, hydroxide, oxide, sub-oxide, or a combination thereof

19. The method of claim 9, wherein both surfaces of each layer have said surface terminations comprising alkoxide, fluoride, hydroxide, oxide, sub-oxide, or a combination thereof.

20. The method of claim 1, wherein the coating comprises a polymer composite comprising an organic polymer.

21. The method of claim 21, wherein the organic polymer contains an aryl or heteroaryl moiety and/or one or more, preferably a plurality of, oxygen-containing functional groups, amine-containing functional groups and/or thiol-containing functional groups

22. The method of claim 21, wherein the organic polymer comprises a polysaccharide polymer, preferably an alginate or modified polymer.

23. The method of claim 20, wherein the substantially two-dimensional array of crystal cells defines a plane, and said plane is substantially aligned with the plane of the polymer composite.

24. The method of claim 1, wherein the coating comprising an inorganic composite comprising a glass embedded or coated with the two-dimensional transition metal carbide.

25. The method of claim 1, wherein coating comprising a two-dimensional transitional metal carbide composition has an electrically conductive or semi-conductive surface, preferably having a surface conductivity of at least 250 S/cm, 2500 S/cm, or 4500 S/cm (to about 8000 S/cm.

26. The method of claim 1, wherein coating has a thickness in a range of from about 2 to 3 microns, 3 to 4 microns, 4 to 5 microns, 5 to 6 microns, 6 to 8 microns, 8 to 10 microns, 10 to 12 microns, or a range combining any two or more of these ranges.

27. The method of claim 1, wherein the coating exhibits a EMI shielding, over a frequency range of from 8 to 13 GHz, in a range of from 10 to 15 dB, from 15 to 20 dB, from 20 to 25 dB, from 25 to 30 dB, from 30 to 35 dB, from 35 to 40 dB, from 40 to 45 dB, from 45 to 50 dB, from 50 to 55 dB, from 55 to 60 dB, from 60 to 65 dB, from 65 to 70 dB, from 70 to 75 dB, from 75 to 80 dB, from 80 to 85 dB, from 85 to 90 dB, from 90 to 95 dB or a range combining any two or more of these ranges.

28. A bonded composite composition coating comprising any one or more two-dimensional transition metal carbide and one or more polymers and copolymers comprising oxygen-containing functional groups (e.g., —OH and/or —COOH) and/or amine-containing functional groups and/or thiol-containing functional groups, wherein the oxygen-containing functional groups (—OH, —COO, and ═O) and/or amine-containing functional groups and/or thiol are bonded or are capable of bonding with the surface functionalities of the two-dimensional transition metal carbide materials, and wherein the polymers/copolymers and MXene material are present in a weight ratio range of from 2:98 to 5:95, from 5:95 to 10:90, from 10:90 to 20:80, from 20:80 to 30:70, from 30:70 to 40:60, from 40:60 to 50:50, from 50:50 to 60:40, from 60:40 to 70:30, from 70:30 to 80:20, from 80:20 to 90:10, from 90:10 to 95:5, from 95:5 to 98:2, or a range combining two or more of these ranges.

29. The bonded composite composition coating of claim 28, that exhibits an electrically conductive or semi-conductive surface, preferably having a surface conductivity of at least 250 S/cm, 2500 S/cm, or 4500 S/cm to about 8000 S/cm.

30. The bonded composite composition coating of claim 28, having a thickness in a range of from about 2 to 3 microns, 3 to 4 microns, 4 to 5 microns, 5 to 6 microns, 6 to 8 microns, 8 to 10 microns, 10 to 12 microns, or a range combining any two or more of these ranges.

31. The bonded composite composition coating of claim 28, that exhibits a EMI shielding, over a frequency range of from 8 to 13 GHz, in a range of from 10 to 15 dB, from 15 to 20 dB, from 20 to 25 dB, from 25 to 30 dB, from 30 to 35 dB, from 35 to 40 dB, from 40 to 45 dB, from 45 to 50 dB, from 50 to 55 dB, from 55 to 60 dB, from 60 to 65 dB, from 65 to 70 dB, from 70 to 75 dB, from 75 to 80 dB, from 80 to 85 dB, from 85 to 90 dB, from 90 to 95 dB, or a range combining any two or more of these ranges.
